(19) United States
(12) Patent Application Publication
(10) Pub. No.: US 2023/0317648 A1
(43) Pub. Date: Oct. 5, 2023

(54) Semiconductor Devices and Methods of Manufacture

(71) Applicant: Taiwan Semiconductor Manufacturing Co., Ltd., Hsinchu (TW)

(72) Inventors: Chen-Yu Tsai, Taoyuan City (TW); Ku-Feng Yang, Baoshan Township (TW); Tsang-Jiuh Wu, Hsinchu (TW); Wen-Chih Chiou, Zhunan Township (TW)

(21) Appl. No.: 17/740,618

(22) Filed: May 10, 2022

Related U.S. Application Data
(60) Provisional application No. 63/268,866, filed on Mar. 4, 2022.

(51) Int. Cl. H01L 23/00

(52) U.S. Cl. CPC H01L 24/05; H01L 24/03; H01L 24/06; H01L 24/08; H01L 24/80; H01L 2224/0391; H01L 2224/05009; H01L 2224/05011; H01L 2224/05015; H01L 2224/05017; H01L 2224/05083; H01L 2224/05091; H01L 2224/05124; H01L 2224/05147; H01L 2224/05555; H01L 2224/05557; H01L 2224/0603; H01L 2224/06102; H01L 2224/08146; H01L 2224/08147; H01L 2224/80895; H01L 2224/80896; H01L 2924/3511; H01L 2924/37001

(57) ABSTRACT

Semiconductor devices and methods of manufacture are presented which form metallization layers over a semiconductor substrate; form a first pad over the metallization layers; deposit one or more passivation layers over the first pad; and form a first bond pad via through the one or more passivation layers and at least partially through the first pad.

### PRIORITY CLAIM AND CROSS-REFERENCE

This application claims the benefit of U.S. Provisional Application No. 63/268,866, filed on Mar. 4, 2022, which application is hereby incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor technologies further advance, stacked semiconductor devices, e.g., 3D integrated circuits (3DIC), have emerged as effective to further reduce the physical size of a semiconductor device. In a stacked semiconductor device, active circuits such as logic, memory, processor circuits and the like are fabricated on different semiconductor wafers. Two or more semiconductor wafers may be installed on top of one another to further reduce the form factor of the semiconductor device. However, further improvements in these devices and how they are connected together are desired in order to further reduce the size and improve the operating characteristics of the devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a deposition of layers for a first pad, in accordance with some embodiments.

FIG. 2 illustrates placement and patterning of a photoresist, in accordance with some embodiments.

FIG. 3 illustrates a patterning with the photoresist, in accordance with some embodiments.

FIG. 4 illustrates a removal of the photoresist, in accordance with some embodiments.

FIG. 5 illustrates deposition of a first passivation layer, in accordance with some embodiments.

FIG. 6 illustrates deposition of a second passivation layer, in accordance with some embodiments.

FIG. 7 illustrates a planarization process, in accordance with some embodiments.

FIG. 8 illustrates deposition of a third passivation layer, in accordance with some embodiments.

FIG. 9 illustrates deposition of a fourth passivation layer, in accordance with some embodiments.

FIG. 10 illustrates deposition of an antireflective layer, in accordance with some embodiments.

FIG. 11 illustrates placement of a photoresist, in accordance with some embodiments.

FIG. 12 illustrates an etching process, in accordance with some embodiments.

FIG. 13 illustrates placement of another photoresist, in accordance with some embodiments.

FIG. 14 illustrates an etching process with the another photoresist, in accordance with some embodiments.

FIG. 15 illustrates a deposition of conductive material, in accordance with some embodiments.

FIGS. 16A-16S illustrate a planarization process and a close-up view after the planarization process, in accordance with some embodiments.

FIG. 17 illustrates a bonding process, in accordance with some embodiments.

FIG. 18 illustrates placement of a photoresist to form a first pad, in accordance with some embodiments.

FIGS. 19A-19B illustrate an etching process to form a circular first pad, in accordance with some embodiments.

FIG. 20 illustrates formation of an opening through the first pad, in accordance with some embodiments.

FIGS. 21A-21B illustrate formation of a first bond pad via, in accordance with some embodiments.

FIGS. 22A-22X illustrate top down views of different embodiments of the first bond pad via, in accordance with some embodiments.

FIG. 23 illustrates a bonding process, in accordance with some embodiments.

FIG. 24 illustrates formation of a first pad, in accordance with some embodiments.

FIG. 25 illustrates formation of a second pad, in accordance with some embodiments.

FIG. 26 illustrates a planarization process, in accordance with some embodiments.

FIG. 27 illustrates deposition of a plurality of passivation layers, in accordance with some embodiments.

FIG. 28 illustrates formation of an opening to the metallization layers, in accordance with some embodiment.

FIG. 29 illustrates formation of the first bond pad via, in accordance with some embodiments.

FIGS. 30A-32B illustrate top down views of the first pad and the second pad, in accordance with some embodiments.

FIG. 33 illustrates a bonding process, in accordance with some embodiments.

FIG. 34 illustrates an embodiment of the bond pad vias in package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described herein in specific embodiments in which bond pad vias are embedded within or through bond pads in order to help modulate undesirable protrusions when bonding devices together in a system on integrated circuit device at the 5 nanometer node and below. The embodiments presented, however, are not intended to be limited to the precise embodiments described below, as the embodiments and ideas may be implemented in any suitable device or structure.

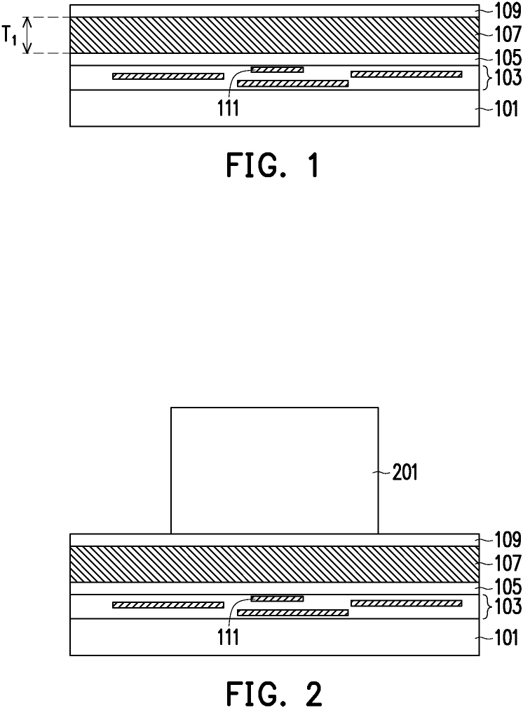

With reference now to FIG. 1, there is illustrated a semiconductor substrate 101, metallization layers 103, a first barrier layer 105, a first pad 107, and a first etch stop layer 109 over the semiconductor substrate 101. In an embodiment the semiconductor substrate 101 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

Active devices (not separately visible in FIG. 1) may be formed on the semiconductor substrate 101. In an embodiment the active devices may comprise a wide variety of active devices such as transistors (planar, finFET, multi-channel, nanostructure, combinations of these, or the like) and the like and passive devices such as capacitors, resistors, inductors and the like that may be used to generate the desired structural and functional parts of the design. The active devices and passive devices may be formed using any suitable methods either within or else on the semiconductor substrate 101.

The metallization layers 103 are formed over the semiconductor substrate 101 and the active devices and are designed to connect the various active devices to form functional circuitry for the design. In an embodiment the metallization layers 103 are formed of layers of dielectric and conductive material and may be formed through any suitable process (such as deposition, damascene, dual damascene, etc.). In an embodiment there may be a first interlayer dielectric layer (ILD), a first metallization layer with a second ILD and contacts embedded within the second ILD, and a third ILD over the second ILD.

In an embodiment the conductive material may be a material such as copper formed using, e.g., a damascene or dual damascene process, whereby an opening is formed within the dielectric material of the metallization layers 103, the opening is filled and/or overfilled with a conductive material such as copper, and a planarization process is performed to embed the conductive material within the dielectric material. However, any suitable material and any suitable process may be used to form the metallization layers 103.

As part of the metallization layers 103, a top metal layer 111 is formed as a top most layer within the metallization layers 103. In an embodiment the top metal layer 111 includes a dielectric layer and conductive features formed within the dielectric layer. The top metal layer 111 may be formed by initially depositing the dielectric layer over a top surface of underlying layers of the metallization layers 103. The dielectric layer may be deposited by chemical vapor deposition (CVD), physical vapor deposition (PVD), or the like. However, any suitable material and method of deposition may be utilized.

Once the dielectric layer has been formed, the dielectric layer may then be etched to form openings exposing a top surface of the underlying layers (not separately illustrated) of the metallization layers 103. In an embodiment the dielectric layer may be etched using, e.g., a via first dual damascene process, whereby a first masking and etching process is utilized to pattern and etch a via pattern at least partially into the dielectric layer. Once the via pattern is etched, a second masking and etching process is utilized to pattern and etch a trench pattern into the dielectric layer, wherein the etching of the trench pattern further extends the via pattern through the dielectric layer to expose the underlying layer.

However, while a via first dual damascene structure is described, this is intended to merely be illustrative and is not intended to be limiting upon the embodiments. Rather, any suitable process or processes may be utilized to form the via openings and trench openings of the top metal layer 111. For example, a trench first dual damascene process, or even multiple single damascene processes, may be utilized. All such processes are fully intended to be included within the scope of the embodiments.

Once the via openings and trench openings have been formed, the conductive features may be formed by depositing conductive material in the via openings and the trench openings using, for example, a plating process. In an embodiment the conductive features may include conductive trenches and conductive vias connecting the conductive trenches to underlying structures. In an embodiment the conductive material may be copper, a copper alloy, aluminum, an aluminum alloy, combinations of these, or the like. However, any suitable material and any suitable process of formation may be utilized.

Once the via openings and trench openings have been filled and/or overfilled by the conductive material, the conductive features may be formed by removing excess material from outside of the via openings and the trench openings. In an embodiment the removal may be performed using a planarization process such as a chemical mechanical polishing (CMP) process. However, any suitable removal process may be utilized.

In another embodiment, instead of using a damascene or dual damascene process to form the conductive features embedded within the dielectric layer, the conductive features may comprise a material such as an aluminum copper alloy. In such an embodiment the conductive features within the top metal layer 111 may be formed by first blanket depositing the material (e.g., aluminum copper) using a deposition process such as physical vapor deposition, chemical vapor deposition, combinations of these, or the like. Once the material has been deposited, the material may be pattered into the desired shape using, e.g., a photolithographic masking and etching process.

Further, once the conductive features have been formed into the desired shape, the dielectric layer may be deposited over the conductive features. In an embodiment the dielectric layer may be deposited as described above in order to cover the conductive features. Once covered, the dielectric layer may be planarized using, e.g., a chemical mechanical polishing process, in order to provide a planar surface for subsequent processing.

Optionally, if desired, once the top metal layer 111 has been formed, the conductive material within the top metal layer 111 may be covered by yet another dielectric layer. In an embodiment the dielectric layer placed over the top metal layer 111 may be deposited using any suitable process such as CVD, ALD, PVD, spin-on, combinations of these, or the like, and may be any suitable material as described above.

FIG. 1 additionally illustrates formation of the first barrier layer 105 overlying the metallization layers 103 (and in electrical connection with at least a portion of the metallization layers 103). In an embodiment the first barrier layer 105 may be a barrier material such as by being a metallic material such as TiN, Ta, Ti, TiAlN, TaC, TaCN, TaSiN, Mn, Zr, TaN, Ru, Mo, WN, other metal oxides, metal nitrides, metal silicates, transition metal-oxides, transition metal-nitrides, transition metal-silicates, oxynitride of metals, metal aluminates, zirconium silicate, zirconium aluminate, combinations of these (e.g., a combination of tantalum nitride and tantalum), or the like. In a particular embodiment the first barrier layer 105 comprises a first layer of titanium nitride and a second layer of tantalum. Additionally, the first barrier layer 105 may be deposited using a deposition process such as atomic layer deposition, chemical vapor deposition, sputtering, or the like, to a thickness of between about 5 Å̅ and about 200 Å̅, although any suitable deposition process or thickness may be used.

The first pad 107 is formed over the first barrier layer 105. In an embodiment the first pad 107 is formed of a conductive material such as an aluminum copper alloy (wherein the aluminum copper alloy may have any suitable weight-% of copper doping in the aluminum matrix), although other suitable materials, such as aluminum, copper, tungsten, composite layers of different materials, or the like, may be utilized. The material of the first pad 107 may be formed using a process such as CVD or PVD. The material of the first pad 107 may be deposited to a first thickness T₁ of between about 1 µm and about 3 µm. However, any suitable material, process, and thickness may be utilized.

The first etch stop layer 109 is formed over the first pad 107. In an embodiment the first etch stop layer 109 may be formed of silicon oxynitride (SiON) using plasma enhanced chemical vapor deposition (PECVD), although other materials such as SiN, SiCON, SiC, SiOC, SiCₓN_{y}, SiOₓ, other dielectrics, combinations thereof, or the like, and other techniques of forming the first etch stop layer 109, such as low pressure CVD (LPCVD), PVD, or the like, could be used. The first etch stop layer 109 may have a thickness of between about 5 Å̅ and about 200 Å or between about 5 Å̅ and about 50 Å̅.

FIG. 2 illustrates a placement of a first photoresist 201 over the first etch stop layer 109 in order to initiate patterning of the first pad 107. In an embodiment the first photoresist 201 may be a single layer of photosensitive material or else may be multiple layers of materials, such as by being a tri-layer photoresist with a bottom antireflective coating (BARC) layer, a first intermediate mask layer, and a top photosensitive layer. In an embodiment in which the first photoresist 201 is a single layer of photosensitive material, the first photoresist 201 is applied using, e.g., a spin-on process, and includes a photoresist polymer resin along with one or more photoactive compounds (PACs) in a photoresist solvent. The PACs will adsorb the patterned light source and generate a reactant in those portions of the photosensitive layer that are exposed, thereby causing a subsequent reaction with the photoresist polymer resin that can be developed in order to replicate the patterned energy source within the photosensitive layer.

In an embodiment in which the first photoresist 201 is a tri-layer photoresist, the BARC layer is applied in preparation for an application of the top photosensitive layer. The BARC layer, as its name suggests, works to prevent the uncontrolled and undesired reflection of energy (e.g., light) back into the overlying top photosensitive layer during an exposure of the top photosensitive layer, thereby preventing the reflecting light from causing reactions in an undesired region of the top photosensitive layer. Additionally, the BARC layer may be used to provide a planar surface, helping to reduce the negative effects of the energy impinging at an angle.

The first intermediate mask layer may be placed over the BARC layer. In an embodiment the first intermediate mask layer is a hard mask material such as silicon nitride, oxides, oxynitride, silicon carbide, amorphous silicon, combinations of these, or the like. The hard mask material for the first intermediate mask layer may be formed through a process such as chemical vapor deposition (CVD), although other processes, such as plasma enhanced chemical vapor deposition (PECVD), low pressure chemical vapor deposition (LPCVD), spin-on coating, or even silicon oxide formation followed by nitridation, may alternatively be utilized. Any suitable method or combination of methods to form or otherwise place the hardmask material may be utilized, and all such methods or combinations are fully intended to be included within the scope of the embodiments. The first intermediate mask layer may be formed to a thickness of between about 50 Å and about 500 Å, such as about 300 A.

In an embodiment the top photosensitive layer is applied over the first intermediate mask layer using, e.g., a spin-on process, and includes a photoresist polymer resin along with one or more photoactive compounds (PACs) in a photoresist solvent. The PACs will adsorb the patterned light source and generate a reactant in those portions of the top photosensitive layer that are exposed, thereby causing a subsequent reaction with the photoresist polymer resin that can be developed in order to replicate the patterned energy source within the top photosensitive layer.

Once the first photoresist 201 has been applied, the photosensitive layer is exposed to a patterned energy source (e.g., light) and developed in order to form a first mask in the photosensitive layer. Once the photosensitive layer has been patterned, and in embodiments in which the first photoresist 201 is a tri-layer photoresist, the top photosensitive layer may be used as a mask along with one or more etch processes in order to pattern the underlying BARC layer and the first intermediate mask layer.

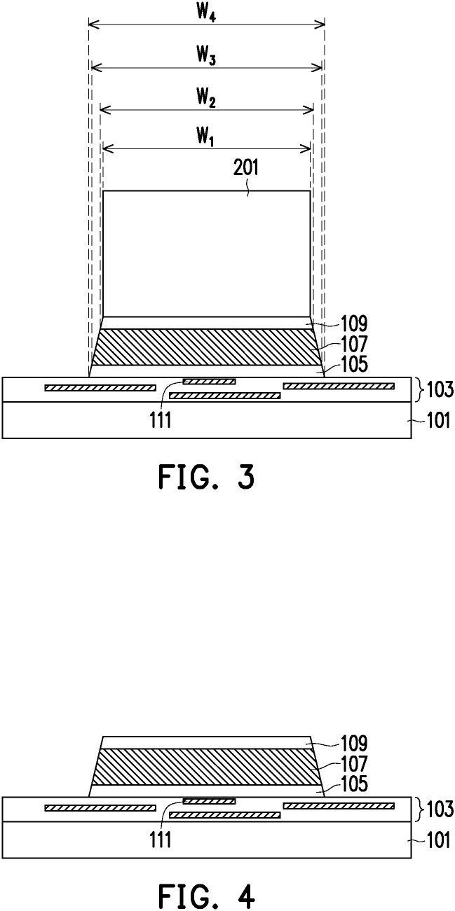

FIG. 3 illustrates a patterning of the first etch stop layer 109, the first pad 107, and the first barrier layer 105 using the first photoresist 201 as a mask. In an embodiment the first etch stop layer 109, the first pad 107, and the first barrier layer 105 are patterned using one or more etch processes, such as one or more reactive ion etch processes. However, any suitable etching process may be utilized.

For example, in a particular embodiment in which the first etch stop layer 109 is silicon oxynitride, the first pad 107 is aluminum copper, and the first barrier layer 105 is a combination of tantalum nitride and tantalum, the patterning process may comprise at least three etching processes. In this embodiment the first etching process may use etchants such as a combination of chlorine (Cl₂) and CₓH_{y}F_{z} to etch the silicon oxynitride, the second etching process may use etchants such as a combination of chlorine along with BCl₃ to etch the aluminum copper, and the third etching process may use etchants such as a combination of chlorine, BCl₃, and argon in order to etch the combination of tantalum nitride and tantalum. However, any suitable combination of processes and etchants may be utilized.

In an embodiment the structure formed by the etching of the first pad 107, the first etch stop layer 109, and the first barrier layer 105 may be trapezoidal in shape. As such, the first etch stop layer 109 may have a first width W₁ at a top of the structure of between about 3 µm and about 10 µm, the first pad 107 may have a second width W₂ at a top of the first pad 107 of between about 3.01 µm and about 10.01 µm, the first pad 107 may have a third width W₃ at a bottom of the first pad 107 of between about 3.5 µm and about 10.5 µm, and the first barrier layer 105 may have a fourth width W₄ at a bottom of the structure of between about 3.51 µm and about 10.51 µm. However, any suitable widths may be utilized.

FIG. 4 illustrates a removal of the first photoresist 201 after the etching of the first pad 107, the first etch stop layer 109, and the first barrier layer 105. In an embodiment the first photoresist 201 may be removed using a series of one or more etches, such as an etch utilizing etchants such as CₓF_{y}, O₂, H₂O, and N₂ (performed, for example, in a same etching tool in another vacuum chamber as the previous etch). However, any suitable removal processes, such as ashing processes, may be utilized.

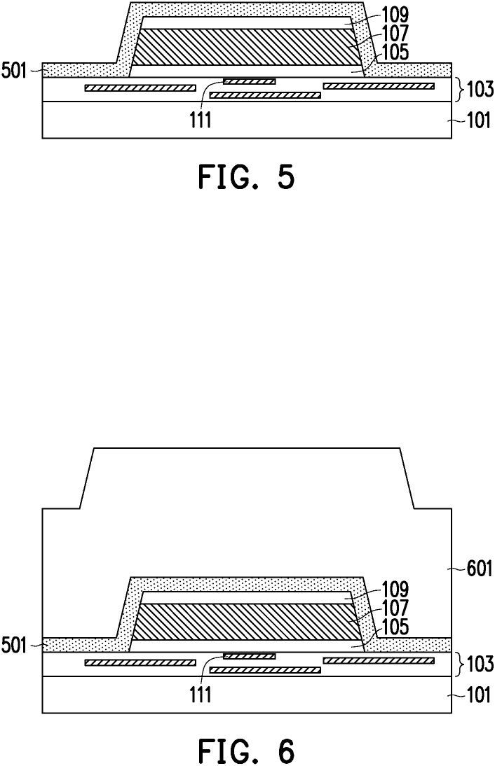

FIG. 5 illustrates a deposition of a first passivation layer 501 over the first etch stop layer 109. In an embodiment the first passivation layer 501 may be a dielectric material such as silicon nitride, silicon oxide, silicon oxynitride, silicon carbide, silicon oxycarbide, combinations of different layers of these, or the like, using a deposition process such as chemical vapor deposition, physical vapor deposition, atomic layer deposition, combinations of these, or the like. However, any suitable materials and methods of deposition may be utilized.

FIG. 6 illustrates a deposition of a second passivation layer 601 over the first passivation layer 501. In an embodiment the second passivation layer 601 may be another dielectric material different from the first passivation layer 501, such as silicon oxide, silicon nitride, silicon oxynitride, silicon carbide, combinations of these, or the like, using a deposition process such as chemical vapor deposition, physical vapor deposition, atomic layer deposition, combinations of these, or the like. However, any suitable materials and methods of deposition may be utilized.

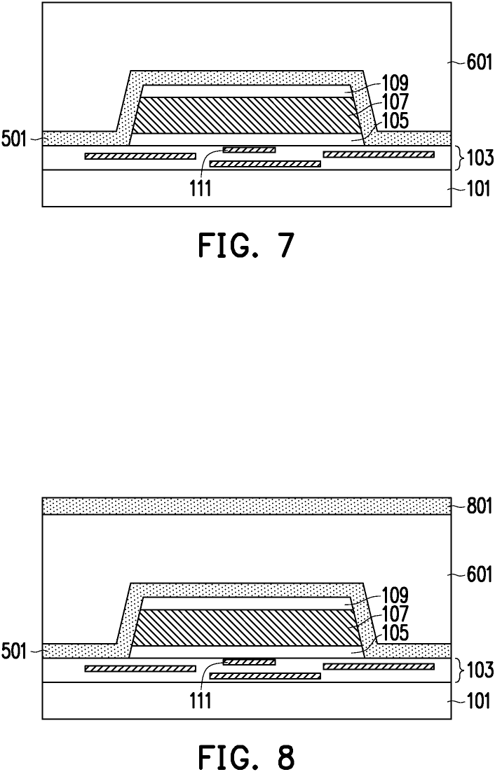

FIG. 7 illustrates a planarization process that is used to planarize the second passivation layer 601 in order to provide a planar surface for subsequent depositions. In an embodiment the planarization process may be a process such as a chemical mechanical polishing process, a grinding process, one or more etch back processes, combinations of these, or the like. However, any suitable planarization process may be utilized.

FIG. 8 illustrates deposition of a third passivation layer 801 over the second passivation layer 601. In an embodiment the third passivation layer 801 may be a dielectric material such as silicon nitride, silicon oxynitride, silicon carbide, silicon oxycarbide, combinations of these, or the like, using a deposition process such as chemical vapor deposition, physical vapor deposition, atomic layer deposition, combinations of these, or the like. However, any suitable materials and methods of deposition may be utilized.

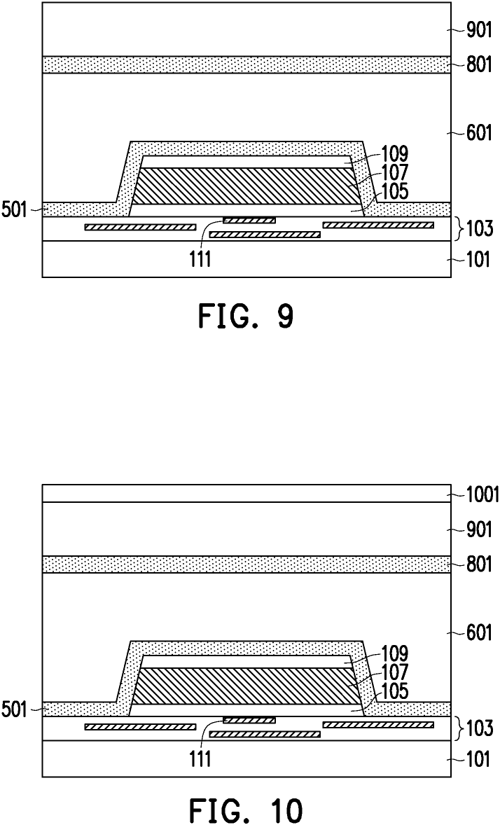

FIG. 9 illustrates deposition of a fourth passivation layer 901 over the third passivation layer 801. In an embodiment the fourth passivation layer 901 may be another dielectric material different from the third passivation layer 801, such as silicon oxide, silicon nitride, silicon oxynitride, silicon carbide, combinations of these, or the like, using a deposition process such as chemical vapor deposition, physical vapor deposition, atomic layer deposition, combinations of these, or the like. However, any suitable materials and methods of deposition may be utilized.

FIG. 10 illustrates deposition of a first antireflective layer 1001 over the fourth passivation layer 901. In an embodiment the first antireflective layer 1001 may be an antireflective material such as silicon oxynitride, silicon nitride (SiNₓ), titanium nitride (TiN), combinations of these, or the like, and may be deposited using a deposition method such as chemical vapor deposition, physical vapor deposition, atomic layer deposition, combinations of these, or the like. However, any suitable materials and methods of deposition may be utilized.

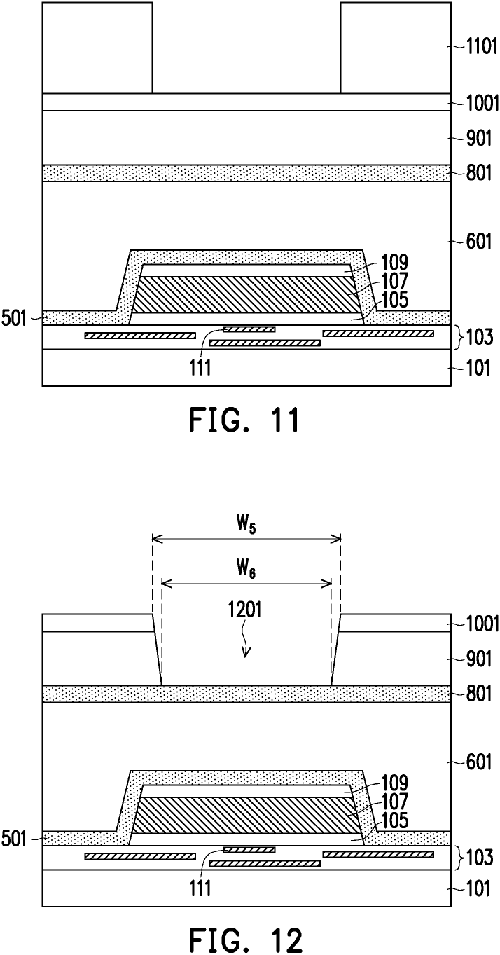

FIG. 11 illustrates placement and patterning of a second photoresist 1101 in order to initiate formation of a first opening 1201 (not illustrated in FIG. 11 but illustrated and described below with respect to FIG. 12). In an embodiment the second photoresist 1101 may be similar to the first photoresist 301 (described above with respect to FIG. 3), such as by being a single layer of photosensitive material or a multi-layer photoresist. In an embodiment the second photoresist 1101 may be placed, imaged, and developed in order to pattern the second photoresist 1101.

FIG. 12 illustrates a formation of the first opening 1201 using the second photoresist 1101 as a mask. In an embodiment the first opening 1201 may be formed using one or more etching processes along with the second photoresist 1101 to remove portions of the first antireflective layer 1001 and the fourth passivation layer 901 before stopping on the third passivation layer 801. However, any suitable etching processes may be utilized.

In an embodiment the first opening 1201 may be formed to have a fifth width W₅ at a top of the fourth passivation layer 901 of between about 5 µm and about 1 µm. Additionally, the first opening 1201 may be formed to have a sixth width W₆ at a bottom of the fourth passivation layer 901 of between about 4.9 µm and about 0.9 µm. However, any suitable widths may be utilized.

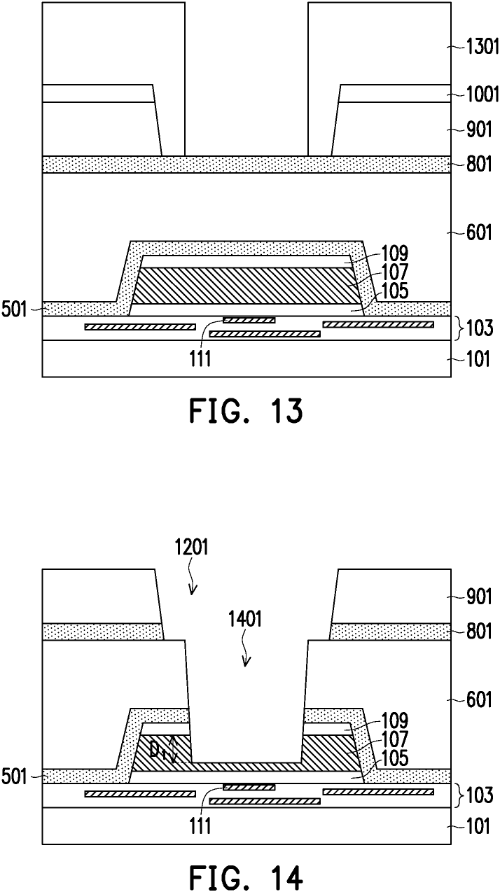

FIG. 13 illustrates placement and patterning of a third photoresist 1301 in order to initiate formation of a second opening 1401 (not illustrated in FIG. 13 but illustrated and described below with respect to FIG. 14). In an embodiment the third photoresist 1301 may be similar to the first photoresist 301 (described above with respect to FIG. 3), such as by being a single layer of photosensitive material or a multi-layer photoresist. In an embodiment the third photoresist 1301 may be placed, imaged, and developed in order to pattern the third photoresist 1301.

FIG. 14 illustrates a series of processes in order to form the second opening 1401 (which may otherwise be seen as an extension of the first opening 1201) through the third passivation layer 801, the second passivation layer 601, and the first passivation layer 501. In an embodiment a first etching process may be used to etch through the third passivation layer 801 and the second passivation layer 601. In an embodiment in which the third passivation layer 801 is silicon nitride and the second passivation layer 601 is silicon oxide, the first etching process may be a dry etching process utilizing etchants selective to these materials, such as a combination of CₓF_{y}, argon, oxygen, and CₓO_{y}. However, any suitable etchants and processes may be utilized.

Once the second opening 1401 has been formed through the third passivation layer 801 and the second passivation layer 601, the third photoresist 1301 may be removed. In an embodiment the third photoresist 1301 may be removed using an ashing process, whereby a temperature of the third photoresist 1301 is increased in an ambient environment of reactants such as oxygen and CₓO_{y}. However, any suitable process and/or reactants may be utilized to remove the third photoresist 1301.

Once the third photoresist 1301 has been removed, a liner removal process may be utilized to etch through the first passivation layer 501 and the first etch stop layer 109 to expose the underlying first pad 107 (and, optionally, to remove the first antireflective layer 1001). In an embodiment the liner removal process may be a low-rf power, dry etching process using etchants selective to the materials of the first passivation layer 501 and the first etch stop layer 109. As such, in an embodiment in which the first passivation layer 501 is silicon nitride and the first etch stop layer 109 is silicon oxynitride, the liner removal process may use an etchant such as CₓF_{y} to extend the second opening 1401 through the first passivation layer 501 and the first etch stop layer 109. However, any suitable processes may be utilized.

Once the first pad 107 has been exposed, the second opening 1401 may be extended at least partially, if not fully, into and/or through the first pad 107. In an embodiment the second opening 1401 may be extended using one or more etching processes, such as a sputtering process. For example, in one embodiment a sputter etch utilizing a precursor such as argon may be utilized in order to remove portions of the first pad 107. However, any suitable process may be utilized.

In an embodiment the second opening 1401 may be formed to extend into the first pad 107 a first distance D₁ that is sufficient to help alleviate subsequent issues caused by differences in coefficients of thermal expansion. In a particular embodiment the first distance D₁ may be between about 100 Å and about 9000 Å. However, any suitable distances may be utilized.

Optionally, once the second opening 1401 has been extended into the first pad 107 the first distance D₁, the exposed surfaces may be cleaned to prepare the surfaces for further processes. In an embodiment the cleaning process may be, e.g., a wet cleaning process which puts a wet cleaning chemical in contact with the exposed surfaces. For example, in some embodiments the wet clean chemical may be a liquid such as XM-426 (J.T.Baker®), DuPont™ EKC265™, ACT970 (Versum Materials), deionized water, combinations of these, or the like. However, any suitable chemical and any suitable cleaning process may be utilized.

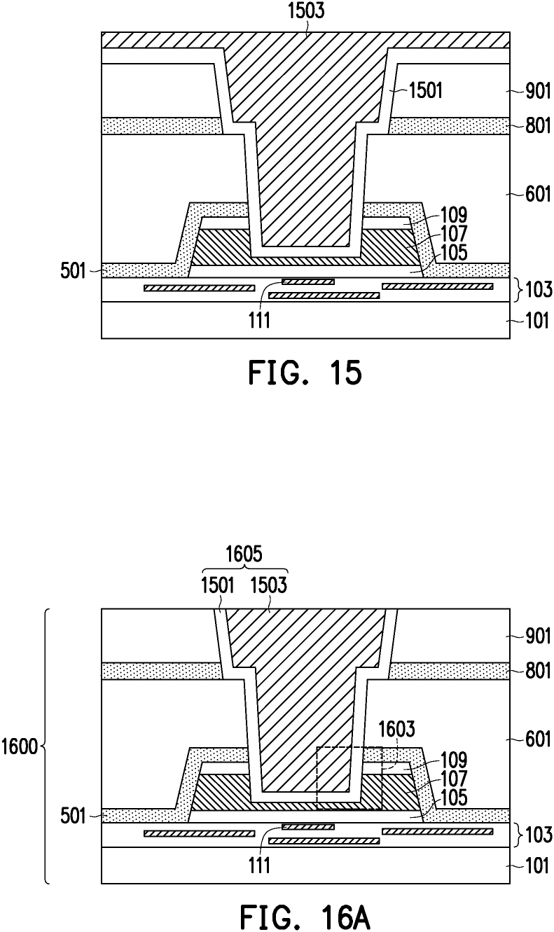

FIG. 15 illustrates deposition of a second barrier layer 1501 and a conductive material 1503 within the first opening 1201 and the second opening 1401. In an embodiment the second barrier layer 1501 may be similar to the first barrier layer 105, such as by being a metallic material such as TiN, Ti, TiAlN, TaC, TaCN, TaSiN, Mn, Zr, TaN, Ru, Mo, WN, other metal oxides, metal nitrides, metal silicates, transition metal-oxides, transition metal-nitrides, transition metal-silicates, oxynitride of metals, metal aluminates, zirconium silicate, zirconium aluminate, combinations of these (e.g., a combination of tantalum nitride and tantalum), or the like. Additionally, the second barrier layer 1501 may be deposited using a deposition process such as atomic layer deposition, chemical vapor deposition, sputtering, or the like, to a thickness of between about 5 Å̅ and about 200 Å̅, although any suitable deposition process or thickness may be used.

To initiate formation of the conductive material 1503, a first seed layer (not separately illustrated) is deposited adjacent to the second barrier layer 1501. In an embodiment the first seed layer is a thin layer of a conductive material that aids in the formation of a thicker layer during subsequent processing steps. The first seed layer may comprise a layer of titanium about 1,000 Å thick followed by a layer of copper about 5,000 Å thick. The first seed layer may be created using processes such as sputtering, evaporation, or PECVD processes, depending upon the desired materials. The first seed layer may be formed to have a thickness of between about 0.3 µm and about 1 µm, such as about 0.5 µm.

Once the first seed layer has been deposited, the conductive material 1503 is deposited to fill and/or overfill the first opening 1201 and the second opening 1401. In an embodiment the conductive material 1503 comprises one or more conductive materials, such as copper, tungsten, other conductive metals, or the like, and may be formed, for example, by electroplating, electroless plating, or the like. In an embodiment, an electroplating process is used wherein the first seed layer is submerged or immersed in an electroplating solution. The first seed layer surface is electrically connected to the negative side of an external DC power supply such that the first seed layer functions as the cathode in the electroplating process. A solid conductive anode, such as a copper anode, is also immersed in the solution and is attached to the positive side of the power supply. The atoms from the anode are dissolved into the solution, from which the cathode, e.g., the first seed layer, acquires the dissolved atoms, thereby plating the exposed conductive areas of the first seed layer.

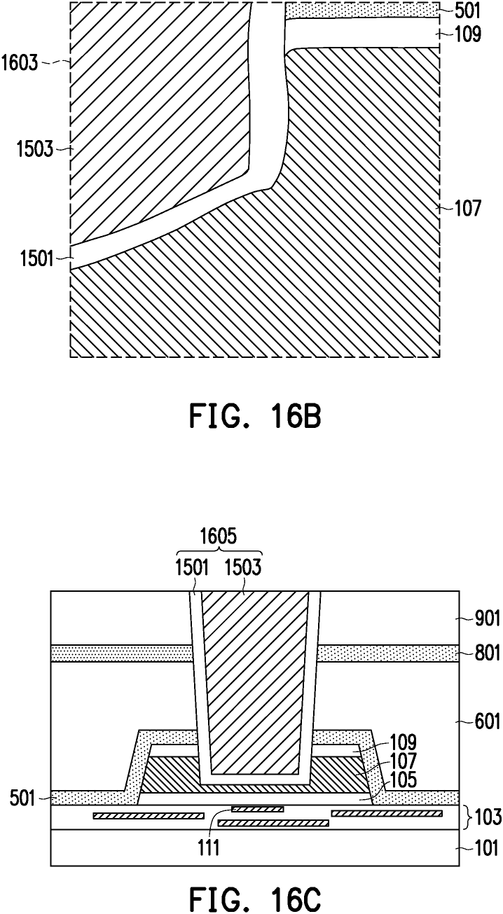

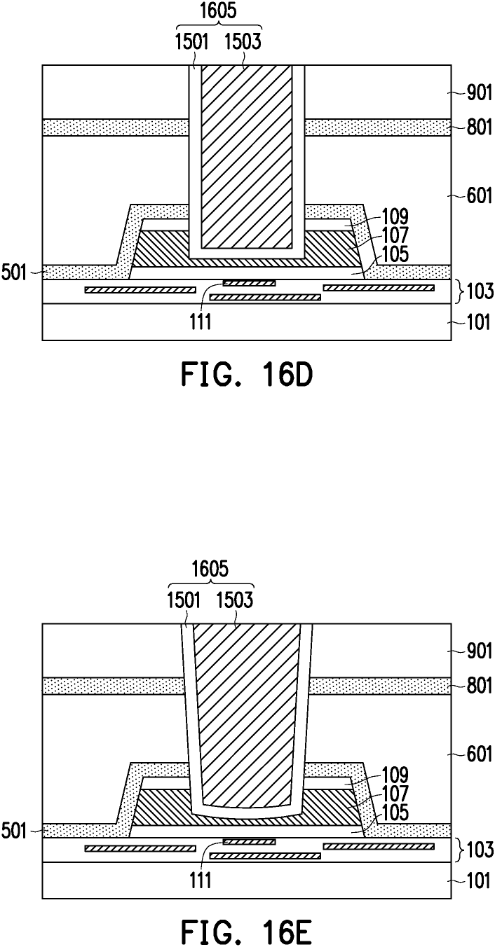

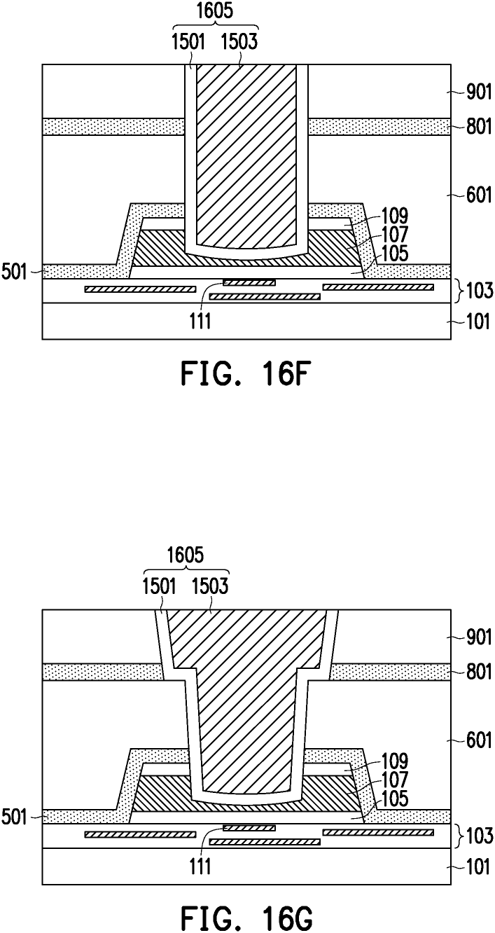

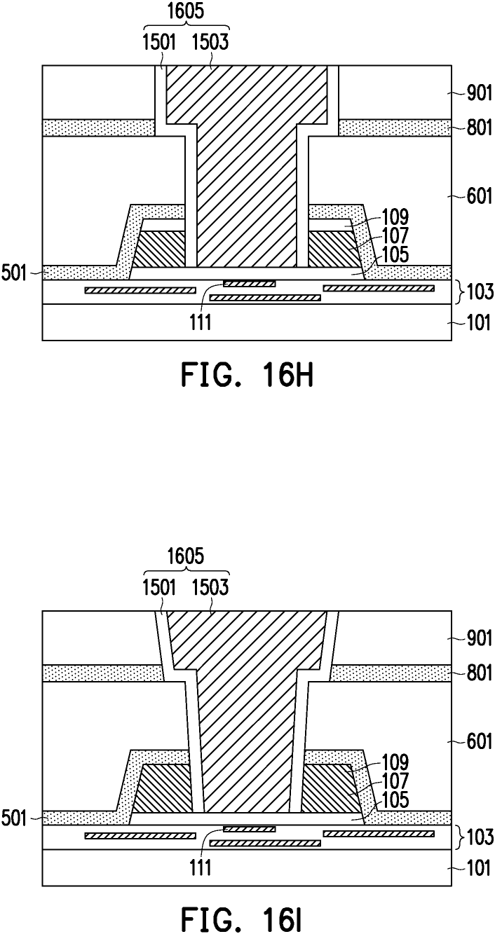

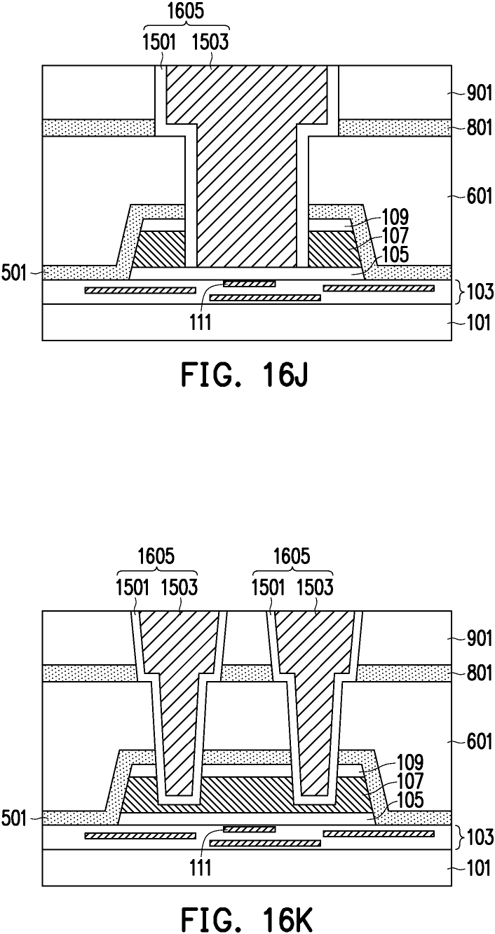

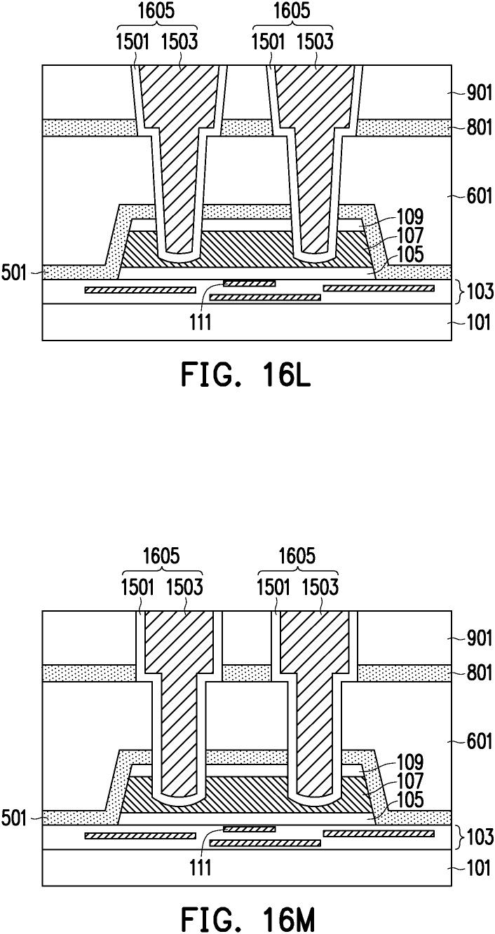

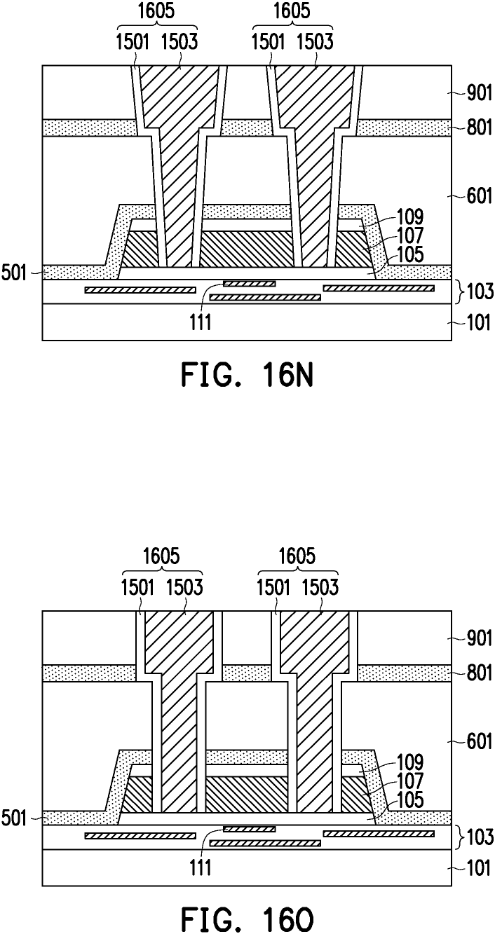

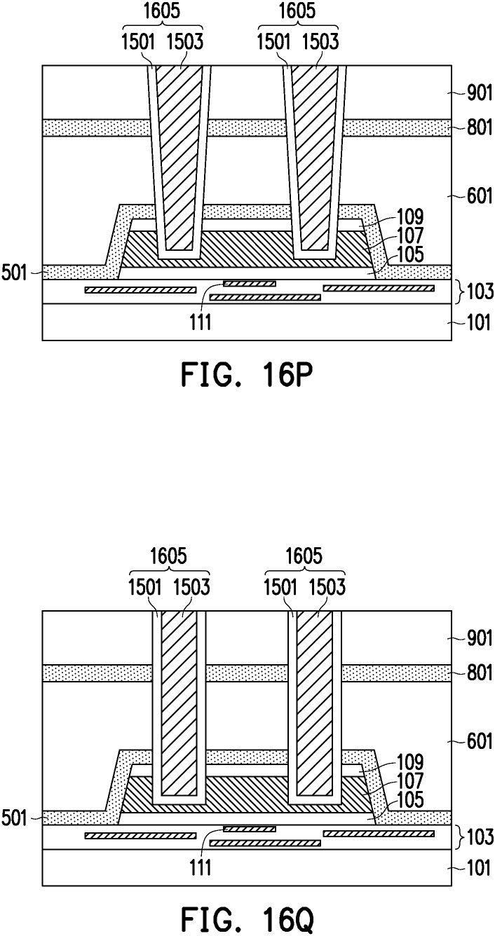

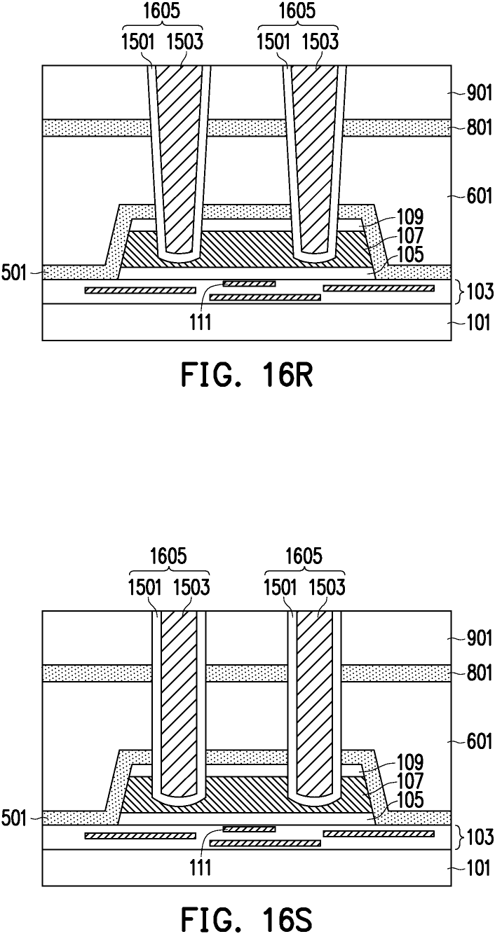

FIG. 16A illustrates a planarization process that is used to planarize the second barrier layer 1501 and the conductive material 1503 in order to form a first bond pad via 1605 and, more broadly, a first semiconductor device 1600. In an embodiment the planarization process may be a process such as a chemical mechanical polishing process, a grinding process, one or more etch back processes, combinations of these, or the like. However, any suitable planarization process may be utilized.

FIG. 16B illustrates a close up view of the dashed box 1603 in FIG. 16A. In this close-up view the corner of the second barrier layer 1501 and conductive material 1503 can be seen in greater detail. In particular, because of the etching process extending the second opening 1401 into the first pad 107 (e.g., the argon plasma sputtering), the corner of the second barrier layer 1501 is rounded more than other etching processes would allow. Such rounding helps to further alleviate stresses that would otherwise occur.

FIGS. 16C-16F illustrate different embodiments in which the first bond pad via 1605 is partially landed within the first pad 107. In these embodiments, however, on the second opening 1401 is formed, and the formation of the first opening 1201 is not utilized. As such, the first bond pad via 1605 has straight sidewalls instead of having different sidewalls sections. Additionally, the straight sidewalls may either be slanted with respect to the underlying semiconductor substrate 101 (as illustrated in FIG. 16C) or else may be perpendicular with respect to the underlying semiconductor substrate 101 (as illustrated in FIG. 16D).

FIGS. 16E and 16F illustrates embodiments similar to FIGS. 16C and 16D, respectively, in which the first opening 1201 is not formed and the first bond pad via 1605 has straight sidewalls. In this embodiment, however, the etching process parameters (e.g., AC bias, RF power, pressure, time of the argon bombardment) are modified and tuned so that the bottom of the second opening 1401 is rounded during the etching process. As such, while the sidewalls of the first bond pad via 1605 may be straight, the bottom has a curvature to it.

FIG. 16G and FIG. 16H illustrate embodiments similar to FIGS. 16E and 16F, respectively, which utilize a curved bottom to the first bond pad via 1605. In these embodiments, however, the first opening 1201 is used in the formation of the first bond pad via 1605. As such, the first bond pad via 1605 will have multiple straight segments along the sidewalls, with FIG. 16G illustrating an embodiment in which the straight segments are slanted with respect to the semiconductor substrate 101 and FIG. 16H illustrating an embodiment in which the straight segments are perpendicular with respect to the semiconductor substrate 101.

FIGS. 16I-16J illustrates additionally embodiment which utilize the first opening 1201, such that the sidewalls of the first bond pad via 1605 have separate segments that are not aligned with each other. In these embodiments, however, the etching process for forming the second opening 1401 (described above with respect to FIG. 14) is continued (using either the same etchants or a different etchant) until the second opening 1401 extends fully through the first pad 107 and/or the first barrier layer 105 and either the first barrier layer 105 or the underlying metallization layers 103 are exposed beneath the first pad 107. As such, when the first bond pad via 1605 is formed within the first opening 1201 and the second opening 1401, the first bond pad via 1605 is in physical contact with the first barrier layer 105 and possibly the underlying metallization layers 103.

Looking at FIG. 16I, this figure illustrates the first bond pad via 1605 being formed with slanted sidewalls, wherein the slanted sidewalls extend to be in physical contact with the first barrier layer 105, while the bottom of the first bond pad via 1605 is in physical contact with the metallization layers 103. Looking next at FIG. 16J, this figure illustrates the first bond pad via 1605 being formed with perpendicular sidewalls, wherein the perpendicular sidewalls extend to be in physical contact with the first barrier layer 105, while the bottom of the first bond pad via 1605 is in physical contact with the metallization layers 103.

FIGS. 16K through 16S illustrate yet another embodiment in which the first bond pad via 1605 is formed to extend into the first pad 107. In this embodiment, however, a second bond pad via 1607 is also formed in order to extend into the same first pad 107. In this embodiment, during the formation of the first opening 1201 and the second opening 1401, a second first opening 1201 (not separately illustrated) and a second opening 1401 (also not separately illustrated) are formed to expose a second portion of the first pad 107. Once all of the first openings 1201 and the second openings 1401 have been patterned, each one is filled and/or overfilled with the second barrier layer 1501 and the conductive material 1503, and a planarization process is utilized to form the first bond pad via 1605 and the second bond pad via 1607 to the same first pad 107.

Looking next at FIG. 16L, there is illustrated another embodiment with the first bond pad via 1605 and the second bond pad via 1607. In this embodiment the first bond pad via 1605 and the second bond pad via 1607 are formed similar to the embodiment described above with respect to FIG. 16K, but in this embodiment the bottom of both the first bond pad via 1605 and the second bond pad via 1607 are rounded, similar to the embodiment discussed above with respect to FIG. 16E. Additionally in this embodiment, the sidewalls of the first bond pad via 1605 and the second bond pad via 1607 are formed to be slanted with respect to the underlying semiconductor substrate 101.

Looking next at FIG. 16M, there is illustrated an embodiment similar to the embodiment described with respect to FIG. 16L, wherein both the first bond pad via 1605 and the second bond pad via 1607 are at least partially embedded within the first pad 107. In this embodiment, however, the first bond pad via 1605 and the second bond pad via 1607 are formed to have sidewalls that are perpendicular with the underlying semiconductor substrate 101.

Looking next at FIGS. 16N and 16O, there is illustrated additional embodiments similar to the embodiments described above with respect to FIGS. 16M and 16L. In these embodiments, however, instead of only partially embedding the first bond pad via 1605 and the second bond pad via 1607 in the first pad 107, the first bond pad via 1605 and the second bond pad via 1607 are formed to extend fully through the first pad 107. In an embodiment the first bond pad via 1605 and the second bond pad via 1607 may be formed to extend through the first pad 107 as described above with respect to FIG. 16I, although any suitable method may be used.

FIGS. 16P and 16Q illustrate further embodiments in which both the first bond pad via 1605 and the second bond pad via 1607 are formed. In this embodiment, however, the second opening 1401 is formed without forming the first opening 1201. As such, the sidewalls of both the first bond pad via 1605 and the second bond pad via 1607 are formed with straight sidewalls. Further, the straight sidewalls of both the first bond pad via 1605 and the second bond pad via 1607 may be formed to either be slanted with respect to the semiconductor substrate 101 (as illustrated in FIG. 16P) or perpendicular with respect to the semiconductor substrate 101 (as illustrated in FIG. 16Q).

FIGS. 16R and 16S illustrate yet further embodiments in which the second opening 1401 is formed without the first opening 1201 in the formation of both the first bond pad via 1605 and the second bond pad via 1607. In this embodiment the first bond pad via 1605 and the second bond pad via 1607 are formed to partially extend into the first pad 107 and the first bond pad via 1605 and the second bond pad. Further, the straight sidewalls of the first bond pad via 1605 and the second bond pad via 1607 are formed to either be slanted with respect to the underlying semiconductor substrate 101 (as illustrated in FIG. 16R) or else perpendicular with respect to the underlying semiconductor substrate 101 (as illustrated in FIG. 16S).

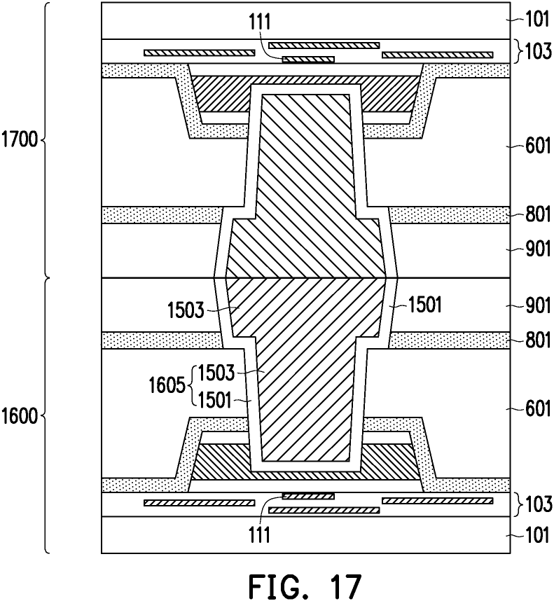

FIG. 17 illustrates a bonding of the first semiconductor device 1600 to a second semiconductor device 1700. In an embodiment the second semiconductor device 1700 has a similar structure with similar materials as the first semiconductor device 1600 and, as such the structures within the second semiconductor device 1700 are labeled with similar reference numbers. However, the second semiconductor device 1700 may also have different structures than the first semiconductor device 1600 while remaining within the scope of the embodiments.

In an embodiment the surfaces of the first semiconductor device 1600 (e.g., the fourth passivation layer 901 and the conductive material 1503 of the first semiconductor device 1600) and the surfaces of the second semiconductor device 1700 (e.g., the fourth passivation layer 901 and the conductive material 1503 of the second semiconductor device 1700) may initially be activated. Activating the top surfaces of the first semiconductor device 1600 and the second semiconductor device 1700 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the hybrid bonding of the first semiconductor device 1600 and the second semiconductor device 1700.

After the activation process, the first semiconductor device 1600 and the second semiconductor device 1700 may be placed into physical contact. In a particular embodiment in which hybrid bonding is utilized, the fourth passivation layer 901 of the first semiconductor device 1600 is placed into physical contact with the fourth passivation layer 901 of the second semiconductor device 1700 and the conductive material 1503 of the first semiconductor device 1600 is placed into physical contact with the conductive material 1503 of the second semiconductor device 1700. With the activation process chemically modifying the surfaces, the bonding process between the materials is begun upon the physical contact.

Once physical contact has begun the bonding process, the bonding may then be strengthened by subjecting the assembly to a thermal treatment. In an embodiment the first semiconductor device 1600 and the second semiconductor device 1700 may be subjected to a temperature between about 200° C. and about 400° C. to strengthen the bond. The first semiconductor device 1600 and the second semiconductor device 1700 may then be subjected to a temperature at or above the eutectic point for material of the conductive material 1503. In this manner, fusion of the first semiconductor device 1600 and the second semiconductor device 1700 forms a hybrid bonded device.

Additionally, while specific processes have been described to initiate and strengthen the hybrid bonds between the first semiconductor device 1600 and the second semiconductor device 1700, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

Also, while hybrid bonding has been described as one method of bonding the first semiconductor device 1600 and the second semiconductor device 1700, this as well is only intended to be illustrative and is not intended to be limiting upon the embodiments. Rather, any suitable method of bonding, such as fusion bonding, copper-to-copper bonding, or the like, may also be utilized. Any suitable method of bonding the first semiconductor device 1600 and the second semiconductor device 1700 may be utilized.

By embedding the first bond pad via 1605 in the first pad 107, subsequent protrusions of the materials (e.g., copper) within the first bond pad via 1605 that can occur during processing (e.g., heating) can be reduced or eliminated. In particular, by embedding the first bond pad via 1605 in the first pad 107, the mismatch in the coefficient of thermal expansions between the first bond pad via 1605 and the first pad 107 can be used to modulate the protrusions that would otherwise occur (especially at temperatures of greater than 280° C.). As such, because the protrusions are minimized, a better bonding yield can be achieved, especially in a system on integrated circuit system with copper-copper bonds.

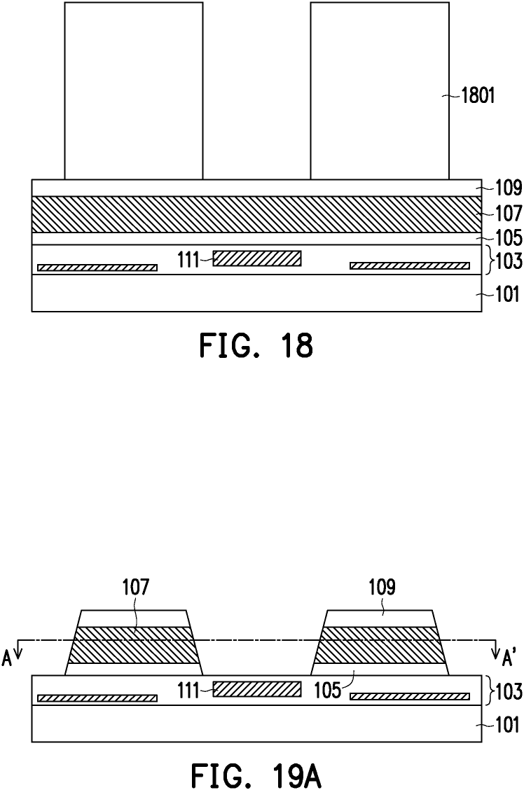

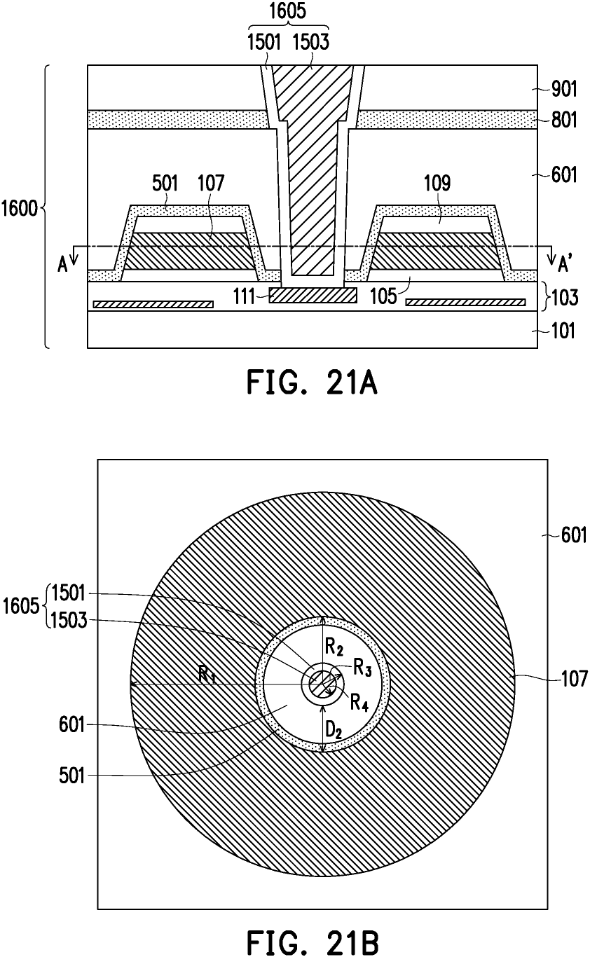

FIGS. 18-23 illustrate another embodiment that may be used in which the first bond pad via 1605 is not formed to extend into a portion of the first pad 107. Rather, the first pad 107 is formed in a circular formation and the first bond pad via 1605 is formed to extend through the first pad 107 without making physical contact with the first pad 107 (as can be seen in FIG. 21A).

To implement this embodiment, and looking first at FIG. 18, there is illustrated a fourth photoresist 1801 that is formed over the structure of FIG. 1. In an embodiment the fourth photoresist 1801 is similar to and formed as the first photoresist 201 described above with respect to FIG. 2, such as being dispensed, imaged, and developed. In this embodiment, however, the fourth photoresist 1801 is circular in shape (in a top down view) and, as such, in the cross-section illustrated in FIG. 18 there appears to be two sections of the fourth photoresist 1801.

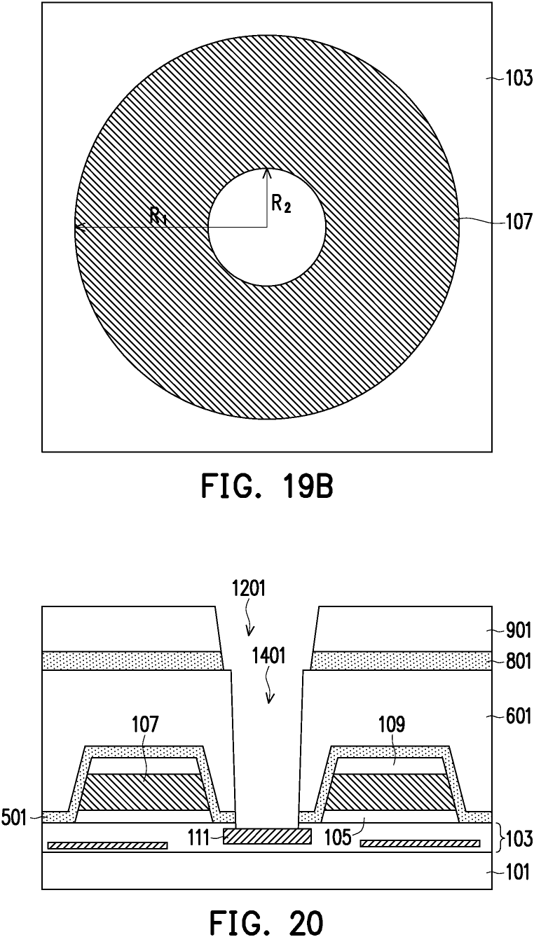

FIG. 19A illustrates that, once the fourth photoresist 1801 has been placed and patterned, the fourth photoresist 1801 is used as a mask to etch the first etch stop layer 109, the first pad 107, and the first barrier layer 105. In an embodiment the first etch stop layer 109, the first pad 107, and the first barrier layer 105 may be etched as described above with respect to FIG. 3, and the fourth photoresist 1801 may be removed as described above with respect to FIG. 4. For example, the first etch stop layer 109, the first pad 107, and the first barrier layer 105 may be etched using a series of one or more dry etches, and the fourth photoresist 1801 may be removed using an etching or ashing process. However, any suitable processes may be utilized.

FIG. 19B illustrates a top down view through line A-A′ in FIG. 19A. In this embodiment, the first pad 107 has a circular shape and has a first radius R₁ (e.g., an outer radius) of between about 5 µm and about 15 µm. Additionally, the first pad 107 has a second radius R₂ (e.g., an inner radius) of between about 2 µm and about 12 µm. However, any suitable dimensions may be utilized.

FIG. 20 illustrates a formation of the first passivation layer 501, the second passivation layer 601, the third passivation layer 801, the fourth passivation layer 901, the first opening 1201 and the second opening 1401. In an embodiment the formation of these layers and openings may be performed as described above with respect to FIGS. 5-14. However, any suitable process may be utilized.

In this embodiment, however, the first opening 1201 and the second opening 1401 do not expose the first pad 107. Rather, the first opening 1201 and the second opening 1401 extend through the inner ring of the first pad 107 such that the first pad 107 encircles a portion of the second opening 1401 but is separated from the second opening 1401 by portions of the first passivation layer 501 and the second passivation layer 601. Additionally, the formation of the second opening 1401 continues until a portion of the metallization layers 103 (e.g., the top metal layer 111) is exposed.

FIG. 21A illustrates that, once the first opening 1201 and the second opening 1401 have been formed to extend through the first pad 107 without physically contacting the first pad 107, the second barrier layer 1501 and the conductive material 1503 may be formed to fill the first opening 1201 and the second opening 1401 and make physical and electrical connection to the metallization layers 103. In an embodiment the second barrier layer 1501 and the conductive material 1503 may be formed as described above with respect to FIG. 15. For example, the second barrier layer 1501 is deposited, the first seed layer is deposited, the conductive material 1503 is electroplated to fill a remainder of the first opening 1201 and the second opening 1401, and a planarization process is performed to remove excess portions of the second barrier layer 1501. As such, the first bond pad via 1605 is formed through the first pad 107 without physically touching it and the first semiconductor device 1600 is formed. However, any suitable processes may be utilized.

FIG. 21B illustrates a top down view of the structure of FIG. 21A through line A-A′. In this view it can be seen that both the first bond pad via 1605 and the first pad 107 (in ring shape) are concentric rings, with the first pad 107 encircling the first bond pad via 1605. In this embodiment, the second barrier layer 1501 has a third radius R₃ that is equal to or less than the second radius R₂, such as being between about 2 KÅ and about 5 µm, while the conductive material 1503 has a fourth radius R₄ of between about 1.5 KÅ and about 4.5 µm. As such, the second barrier layer 1501 is separated from the first pad 107 by a second distance D₂ of between about 2 KÅ and about 3 µm. However, any suitable dimensions may be utilized.

By forming the first pad 107 and the bond pad via 1605 as concentric circles, subsequent protrusions of the materials (e.g., copper) within the first bond pad via 1605 during processing (e.g., heating) can be reduced or eliminated without the first bond pad via 1605 physically touching the first pad 107. In particular, by extending the first bond pad via 1605 through the first pad 107, any protrusions can be modulated by means of the coefficient of thermal expansion mismatch between the first bond pad via 1605 and the first pad 107 (especially at temperatures of greater than 280° C.). As such, because the protrusions are minimized, a better bonding yield can be achieved, especially in a system on integrated circuit system with copper-copper bonds.

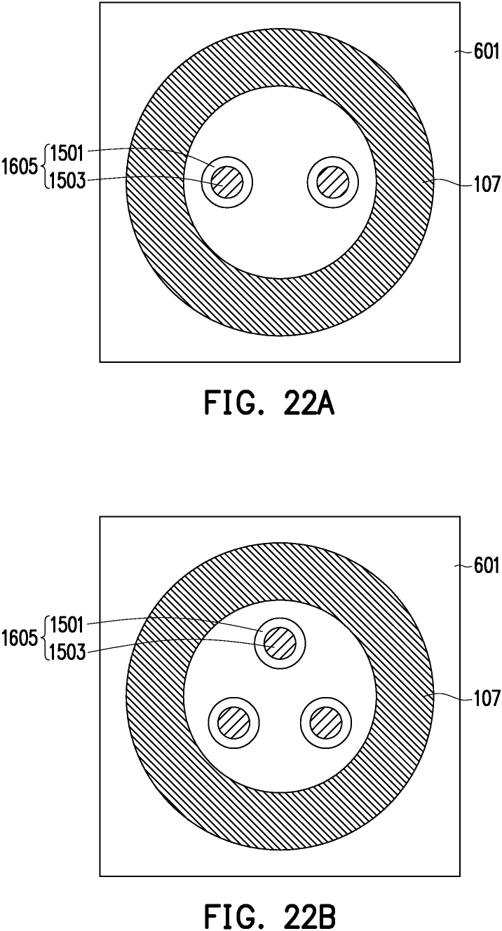

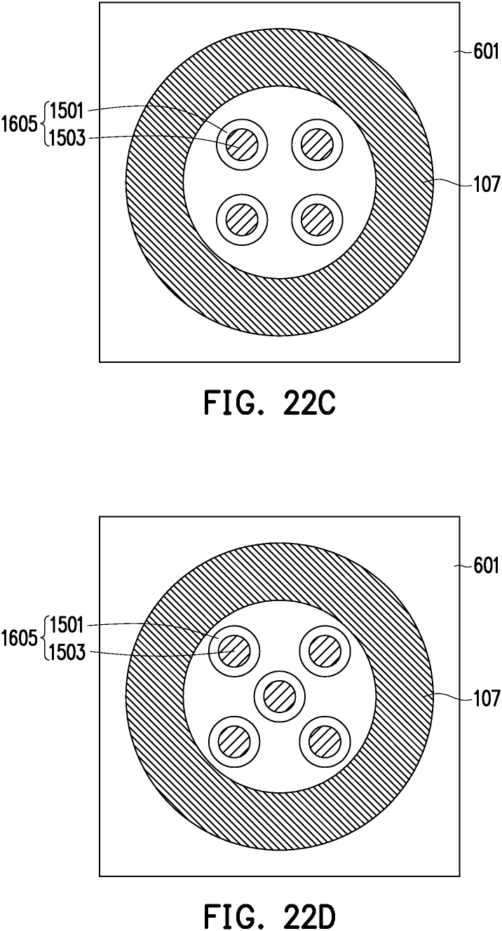

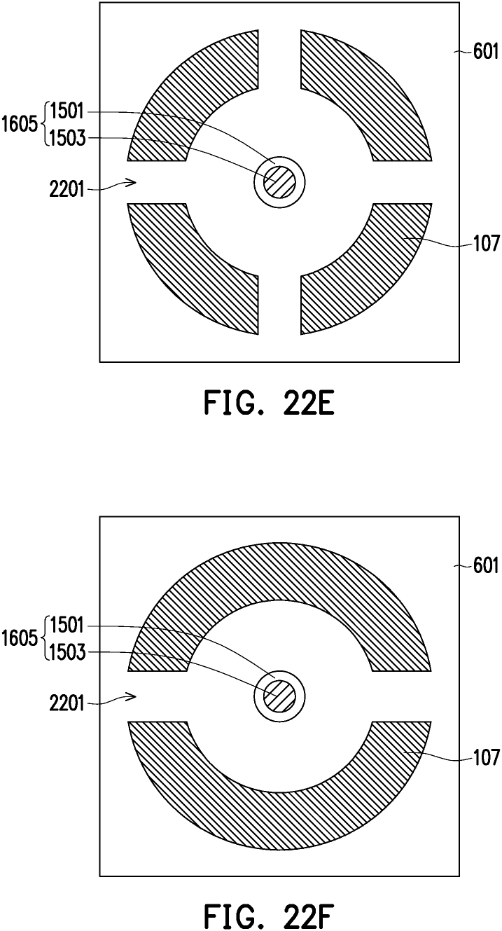

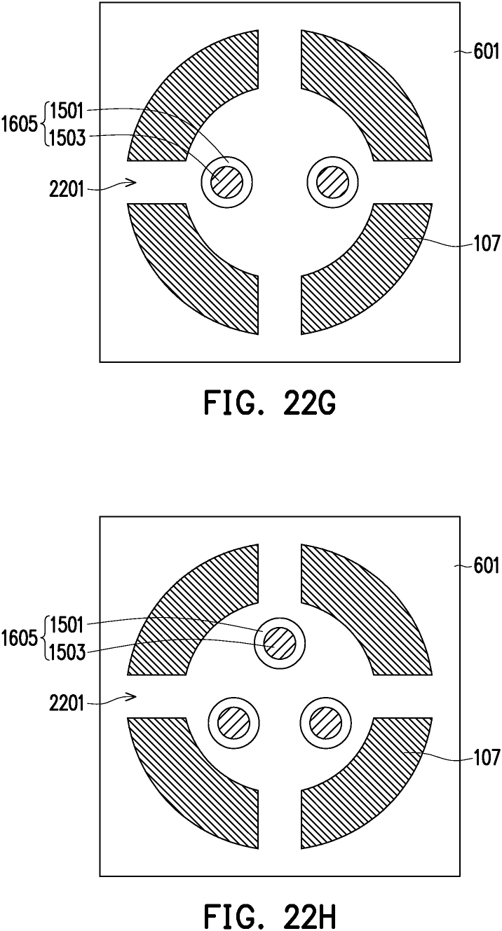

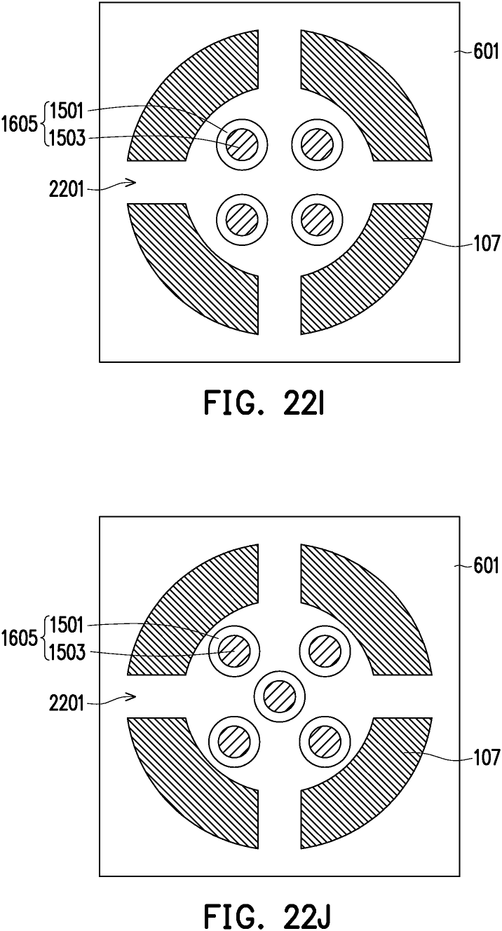

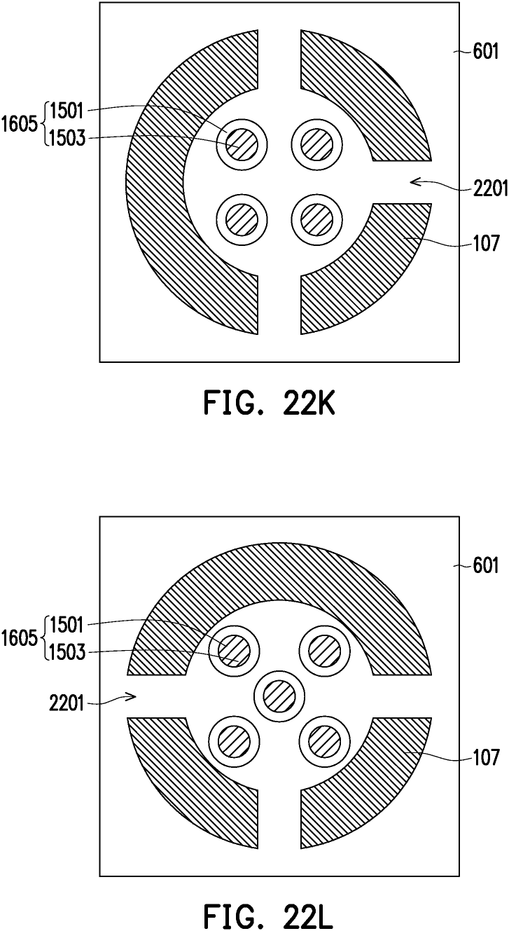

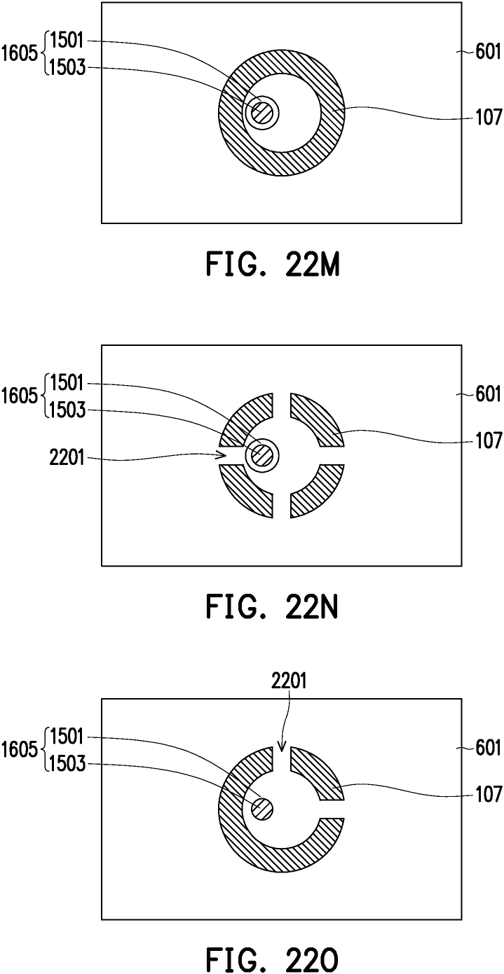

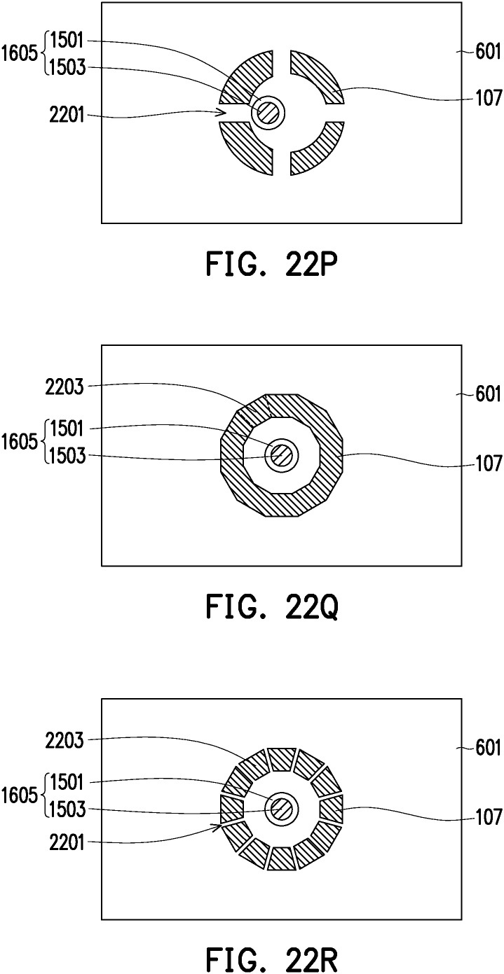

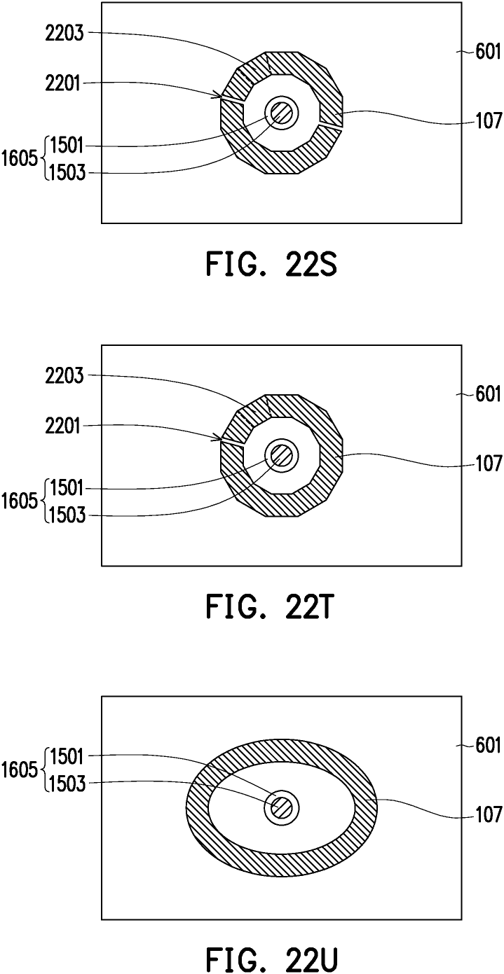

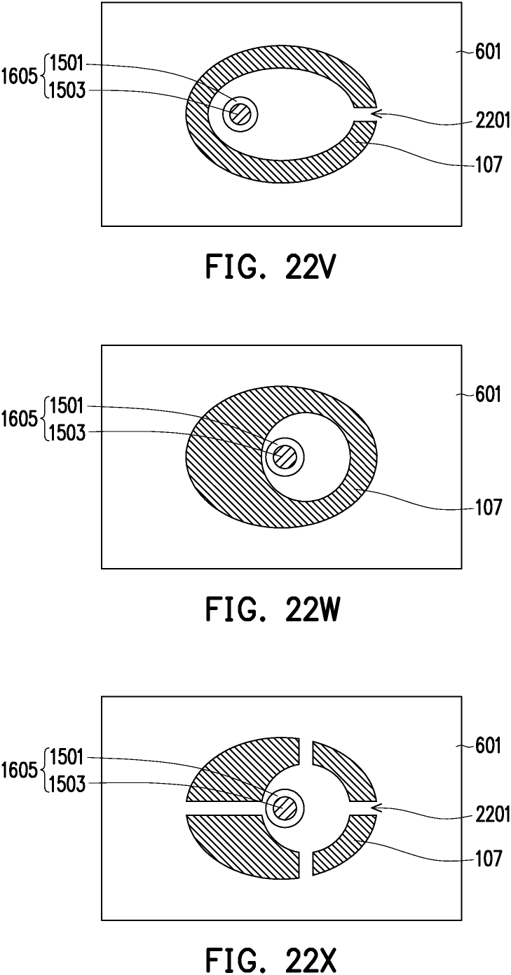

FIGS. 22A-22X illustrate different embodiments that illustrate some of the different configurations that may be used for both the first pad 107 and the first bond pad via 1605 in embodiments in which the first bond pad via 1605 extends through the first pad 107 without touching the first pad 107. Looking first at the embodiment illustrated in FIG. 22A, there is illustrated an embodiment in which, instead of having a single one of the first bond pad vias 1605 through a single one of the first pads 107, two first bond pad vias 1605 extend through the single first pad 107. In other embodiments, there may be a single first bond pad via 1605, wherein the single first bond pad via 1605 has multiple connections to the underlying material (e.g., a single first opening 1201 and multiple second openings 1401) such that the first bond pad via 1605 has a first portion extending through the first pad 107 and a second portion extending through the first pad 107, the first portion being separated from the second portion by at least a portion of the second passivation layer 601.

Looking next at FIGS. 22B-22D, there are illustrated other embodiments in which the number of first bond pad vias 1605 (or the number of second openings 1401) are greater than two. For example, FIG. 22B illustrates an embodiment in which there are three of the first bond pad vias 1605, FIG. 22C illustrates an embodiment in which there are four of the first bond pad vias 1605, and FIG. 22D illustrates an embodiment in which there are five of the first bond pad vias 1605. Any suitable number of first bond pad vias 1605 may be used, and all such numbers are fully intended to be included within the scope of the embodiments.

FIGS. 22E-22L illustrate embodiments which utilize a segmented circular first pad 107 instead of a continuous circular first pad 107. In this embodiment the first pad 107 has one or more third openings 2201 which separate one portion of the first pad 107 from another portion of the first pad 107. In the embodiment illustrated in FIG. 22E, there are four of the third openings 2201 which form a number of segments which are greater than 1 (in this illustrated case 4 segments). However, any suitable number of segments may be utilized.

Additionally illustrated in FIG. 22E, the segmented sections are evenly spaced around the first pad 107. As such, the first pad 107 is discontinuous and symmetrical. However, in other embodiments the individual segments may be asymmetrically formed, which may help mitigate wafer warpage. All such configurations are fully intended to be included within the scope of the embodiments.

FIG. 22F illustrates another embodiment which utilizes a segmented first pad 107. In this embodiment, there is illustrated a first pad 107 that has only two of the third openings 2201, so that the first pad 107 has two segments. However, any suitable number of third openings 2201 and segments may be used.

FIGS. 22G-22J illustrate embodiments similar to the embodiment described above with respect to FIG. 22E (e.g., a segment first pad 107 with four segments). In these embodiments, however, multiple ones of the first bond pad vias 1605 (or multiples ones of the second openings 1401) are surrounded by the discontinuous, segmented first pad 107. For example, FIG. 22G illustrates an embodiment which has two of the first bond pad vias 1605, FIG. 22H illustrates an embodiment which has three of the first bond pad vias 1605, FIG. 22I illustrates an embodiment which has four of the first bond pad vias 1605, and FIG. 22J illustrates an embodiment which has five of the first bond pad vias 1605. Any suitable number of the first bond pad vias 1605 may be used.

FIGS. 22K-22L illustrate embodiments in which the third openings 2201 of the first pad 107 are asymmetrical. As such, while the number of segments may still be greater than one, the third openings 2201 are located such that the individual segments have different lengths and/or shapes. For example, FIG. 22K shows an embodiment that utilizes four of the first bond pad vias 1605 while FIG. 22L shows an embodiment that utilizes five of the first bond pad vias 1605.

FIGS. 22M-22P illustrate further embodiments in which the first bond pad vias 1605 and the first pad 107 are not concentric, such that the first bond pad vias 1605 are located off-center from a center of the first pad 107. For example, FIG. 22M illustrates an embodiment in which the first pad 107 is a single, continuous segment, while FIG. 22N illustrates an embodiment in which the first pad 107 has four segments set out in a symmetrical pattern. FIG. 22O illustrates an embodiment in which the first pad 107 has only two segments set out in an asymmetrical pattern.

FIG. 22P illustrates yet another embodiment in which not only are the third openings 2201 formed so that the first pad 107 has multiple segments in a symmetrical pattern, but the individual widths of the individual segments are not symmetrical. As such, the width of an individual segment on a first side of the first pad 107 is different from an individual segment on a second side of the first pad 107 opposite the first side.

FIGS. 22Q-22T illustrate embodiments in which the first pad 107 utilizes individual polygonal segments 2203 (one of which is illustrated in FIG. 22Q using dashed lines). In these embodiments the individual polygonal segments 2203 have at least three straight sides and angles (e.g., triangles, rectangles, pentagons, etc.), wherein the number of sides and angles are equal and larger than three. FIG. 22Q illustrates an embodiment in which the first pad 107 is continuous and is made up of multiple individual polygonal segments 2203 in physical contact with each other so that the first pad 107 surrounds the first bond pad via 1605. Additionally, the first pad 107 and the first bond pad via 1605 are concentric with each other, although in other embodiments the first pad 107 and the first bond pad via 1605 are not concentric to each other.

FIG. 22R illustrates an embodiment in which the individual polygonal segments 2203 are not in physical contact and are separated from each other by, e.g., the third openings 2201. As such, the first pad 107 is formed as a segmented polygon ring pad, wherein the individual polygonal segments 2203 are symmetric and even as the first pad 107 extends around the first bond pad via 1605.

FIG. 22S illustrates another embodiment which utilizes both individual polygonal segments 2203 that in physical contact with each other to form segments, but wherein at least some of the individual polygonal segments 2203 are also separated from each other by the third openings 2201. In the particular embodiment illustrated, two segments (which each comprise multiple one of the individual polygonal segments 2203) are fully separated from each other by two or more of the third openings 2201. However, any suitable number may be utilized.

FIG. 22T illustrates yet another embodiment which utilizes a number of the individual polygonal segments 2203 in physical contact with adjacent ones of the individual polygonal segments 2203 similar to the embodiment illustrated in FIG. 22S. In this embodiment, however, there is only a single one of the third openings 2201 that interrupts the circular shape of the first pad 107.

FIGS. 22U-22X illustrate additional embodiments in which the general shape of the first pad 107 (instead of being circular or polygonal as described above) has an elliptical shape. Looking first at FIG. 22U, the first bond pad via 1605 is located concentrically within the elliptical shape of the first pad 107, while FIG. 22V illustrates an embodiment in which the first bond pad via 1605 is located off-center and non-concentrically from the first pad 107 in the elliptical shape. Additionally in these embodiments, the first pad 107 may be either continuous all the way around (as illustrated in FIG. 22U) or may have one or more of the third openings 2201 that interrupt the continuousness of the first pad 107 (as illustrated in FIG. 22V). Finally, multiples ones of the first bond pad vias 1605 may be formed within the elliptical first pad 107.

FIGS. 22W and 22X illustrate further embodiments which utilize an elliptical shape. In these embodiments the first pad 107 has a varying width as the first pad 107 encircles the first bond pad via 1605, with the first pad 107 having a larger width on a first side of the first pad 107 and a smaller width on a second side of the first pad 107 opposite the first side. The varying widths may be implemented in either a continuous first pad 107 (as illustrated in FIG. 22W) or in a segmented first pad 107 (as illustrated in FIG. 22X) with four segments. However, any suitable widths and number of segments may be utilized. Finally, multiples ones of the first bond pad vias 1605 may be formed within the elliptical first pad 107.

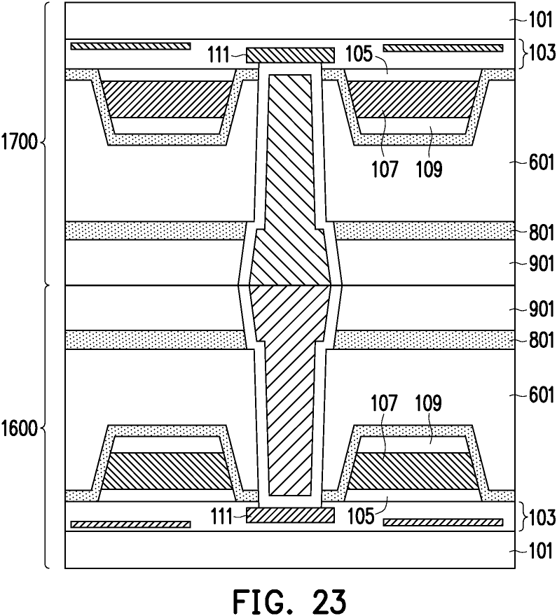

FIG. 23 illustrates a bonding of the first semiconductor device 1600 to the second semiconductor device 1700 in embodiments in which the first bond pad via 1605 extends through the first pad 107 without physically contacting the first pad 107 (as described above with respect to FIGS. 18-22X). In an embodiment the first semiconductor device 1600 may be bonded to the second semiconductor device 1700 as described above with respect to FIG. 17, such as by using a hybrid bonding process. However, any suitable bonding process may be utilized.

By forming the first bond pad vias 1605 as described above, mismatches in the coefficients of thermal expansion between the material of the first bond pad vias 1605 (e.g., copper) and the first pads 701 (e.g., aluminum-copper) can be used as a means to modulate protrusions of the material of the first bond pad vias 1605. This is especially true during annealing processes (e.g., elevated temperatures above 280° C. As such, with a lower thermal expansion, a higher bonding yield can be achieved, especially in embodiments which form 5 nm process node system on integrated circuits.

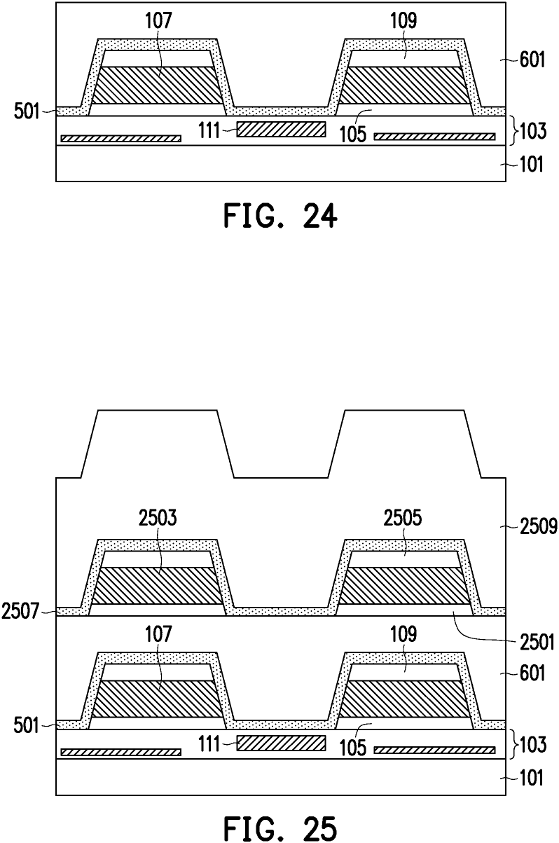

FIGS. 24-33 illustrate yet another embodiment in which the first bond pad via 1605 is formed through the first pad 107 without physically contacting the first pad 107. In these embodiments, however, the first bond pad via 1605 not only passes through the first pad 107 but also passes through a second pad 2503 (not illustrated in FIG. 24 but illustrated and described further below with respect to FIG. 25) overlying the first pad 107. To initiate one formation of these embodiments, and as illustrated in FIG. 24, the first pad 107 is formed as described above with respect to FIG. 18-19B. Additionally, the first passivation layer 501 is deposited as described above with respect to FIG. 5 and the second passivation layer 601 is deposited and planarized as described above with respect to FIGS. 6-7. However, any suitable processes may be utilized.

FIG. 25 illustrates formation of a second barrier layer 2501, a second pad 2503, and a second etch stop layer 2505 over the second passivation layer 601. In an embodiment the second barrier layer 2501, the second pad 2503, and the second etch stop layer 2505 may be formed using similar materials and processes as the first barrier layer 105, the first pad 107, and the first etch stop layer 109 (described above with respect to FIGS. 1-19B). However, any suitable materials and processes may be utilized.

FIG. 25 additionally illustrates the deposition of a fifth passivation layer 2507 and a sixth passivation layer 2509 over the second etch stop layer 2505. In an embodiment the fifth passivation layer 2507 and the sixth passivation layer 2509 may be formed using similar processes and similar materials as the first passivation layer 501 and the second passivation layer 601 as described above with respect to FIGS. 5-6, although any other suitable processes and materials may be utilized.

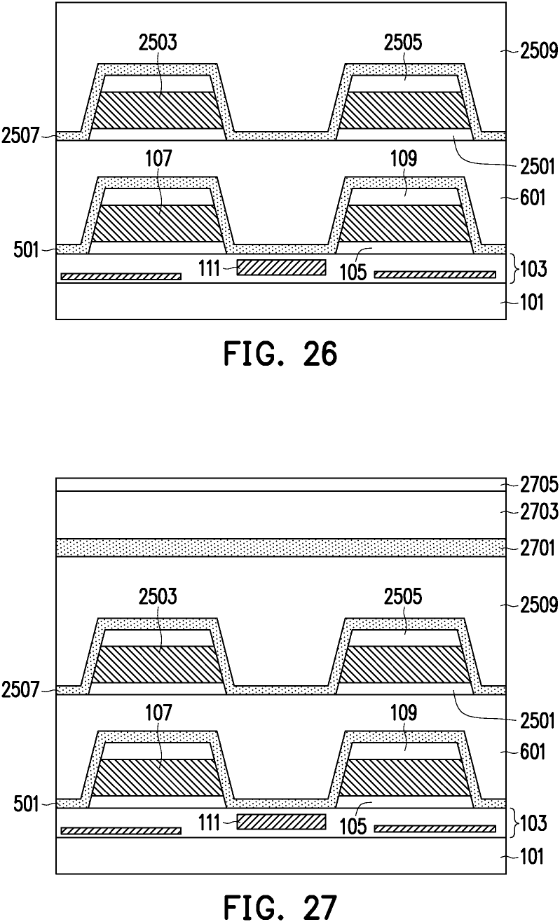

FIG. 26 illustrates a planarization process that is used to planarize the sixth passivation layer 2509 in order to provide a planar surface for subsequent depositions. In an embodiment the planarization process may be a process such as a chemical mechanical polishing process, a grinding process, one or more etch back processes, combinations of these, or the like. However, any suitable planarization process may be utilized.

FIG. 27 illustrates a deposition of a seventh passivation layer 2701, an eighth passivation layer 2703, and a second antireflective layer 2705 over the sixth passivation layer 2509. In an embodiment the seventh passivation layer 2701, the eighth passivation layer 2703, and the second antireflective layer 2705 may be formed using similar materials and similar methods as the third passivation layer 801, the fourth passivation layer 901, and the first antireflective layer 1001 (described above with respect to FIGS. 8, 9 and 10). However, any suitable materials and methods may be utilized.

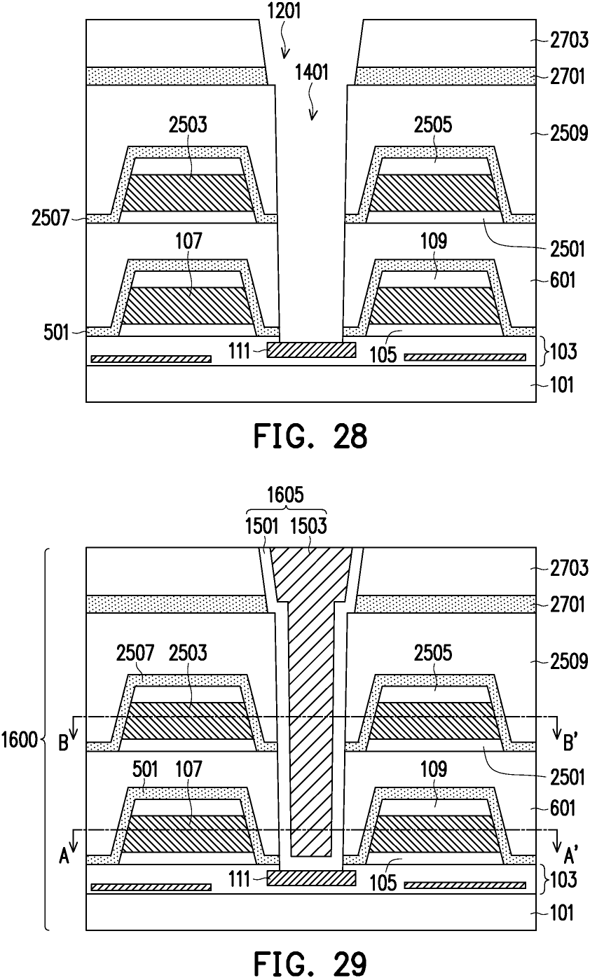

FIG. 28 illustrates a formation of the first opening 1201 and the second opening 1401 through the first passivation layer 501, the second passivation layer 601, the fifth passivation layer 2507, the sixth passivation layer 2509, the seventh passivation layer 2701, the eighth passivation layer 2703, and the second antireflective layer 2705 (along with a subsequent removal of the second antireflective layer 2705). In an embodiment the formation of these openings may be performed as described above with respect to FIGS. 5-20. However, any suitable process may be utilized.

In this embodiment, however, the first opening 1201 and the second opening 1401 do not expose the first pad 107 or the second pad 2503. Rather, the first opening 1201 and the second opening 1401 extend through the inner rings of both the first pad 107 and the second pad 2503 such that both the first pad 107 and the second pad 2503 encircle separate portions of the second opening 1401 and/or the first opening 1201. Additionally in this embodiment, the formation of the second opening 1401 continues until a portion of the metallization layers 103 (e.g., the top metal layer 111) is exposed.

FIG. 29 illustrates that, once the first opening 1201 and the second opening 1401 have been formed, the second barrier layer 1501 and the conductive material 1503 may be formed to fill the first opening 1201 and the second opening 1401 and make physical and electrical connection to the metallization layers 103. In an embodiment the second barrier layer 1501 and the conductive material 1503 may be formed as described above with respect to FIG. 15. For example, the second barrier layer 1501 is deposited, the first seed layer is deposited, the conductive material 1503 is electroplated to fill a remainder of the first opening 1201 and the second opening 1401, and a planarization process is performed to remove excess portions of the second barrier layer 1501, and the conductive material 1503. As such, the first bond pad via 1605 is formed through the first pad 107 and the second pad 2503 without physically touching them and the first semiconductor device 1600 is formed. However, any suitable processes may be utilized.

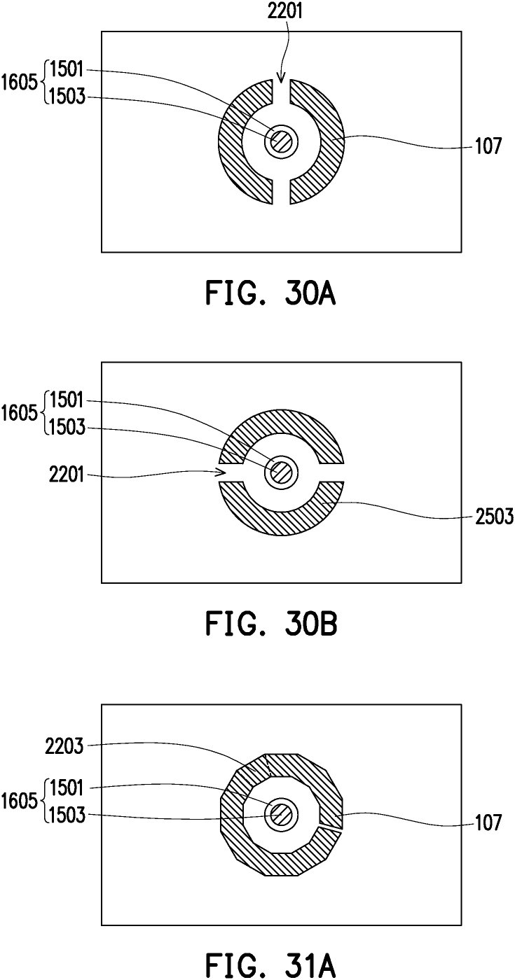

FIGS. 30A and 30B illustrate top down views of the first pad 107 and the second pad 2503 through lines A-A′ and B-B′ in FIG. 29, respectively. In the top down figure illustrated in FIG. 30A, the first pad 107 is a segmented pad with third openings 2201 separating different segments of the first pad 107, and the first pad 107 and the first bond pad via 1605 are concentric with each other. However, any of the shapes (continuous, discontinuous/segmented, polygonal, etc.) and combinations (concentric, non-concentric, etc.) that have been discussed herein may be utilized to shape and locate the first pad 107 and the first bond pad vias 1605.

FIG. 30B illustrates the top down view through line B-B′, and illustrates that, in some embodiments, the second pad 2503 overlying the first pad 107 may be a similar shape as the first pad 107 in a top down view. For example, the second pad 2503 may be a segmented pad with third openings 2201 separating different segments of the second pad 2503. However, any of the shapes (continuous, discontinuous/segmented, polygonal, etc.) and combinations (concentric, non-concentric, etc.) that have been discussed herein may be utilized to shape the first pad 107.

Further, while the shape of the second pad 2503 may be directly aligned with the underlying first pad 107 (e.g., such that the third openings 2201 are aligned with each other), in the embodiment illustrated in FIGS. 30A-30B the second pad 2503 is mis-aligned from the underlying first pad 107, such that the third openings 2201 are not aligned with each other. For example, the second pad 2503 may be rotationally shifted with respect to the first pad 107. Any suitable alignment or mis-alignment are fully intended to be included within the scope of the embodiments.

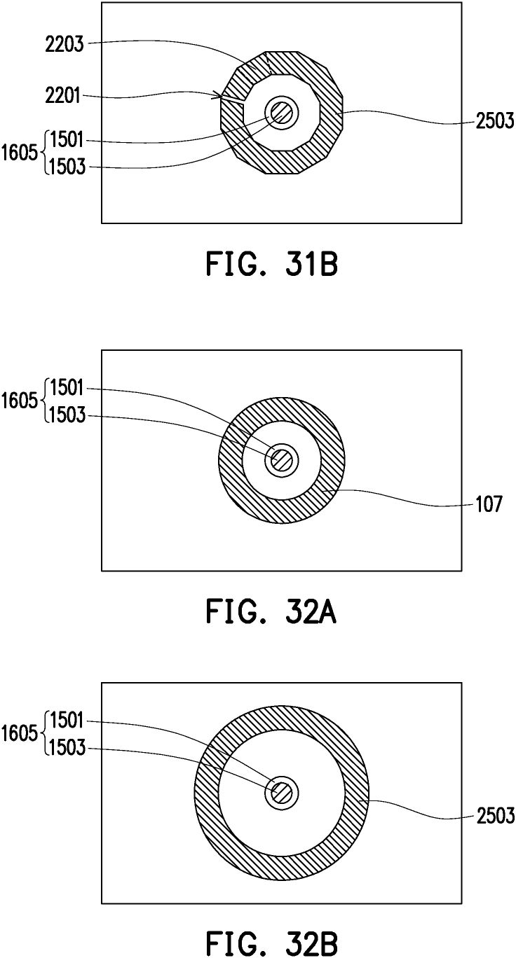

FIGS. 31A and 31B illustrate top down views of the first pad 107 and the second pad 2503 through lines A-A′ and B-B′ in FIG. 29 in embodiments in which both the first pad 107 and the second pad 2503 are polygonal. In the top down figure illustrated in FIG. 31A, the first pad 107 comprises the individual polygonal segments 2203 which are in physical contact with adjacent individual polygonal segments 2203, and the first pad 107 and the first bond pad via 1605 are concentric with each other.

FIG. 31B illustrates that the second pad 2503 overlying the first pad 107 may be a similar shape as the first pad 107 in this top down view. For example, the second pad 2503 may comprise a series of individual polygonal segments 2203, and a single third openings 2201 may separate at least two different ones of the individual polygonal segments 2203 of the second pad 2503. However, any of the shapes (continuous, discontinuous/segmented, polygonal, etc.) and combinations (concentric, non-concentric, etc.) that have been discussed herein may be utilized to shape the first pad 107.

Further, while the shape of the second pad 2503 may be directly aligned with the underlying first pad 107 (e.g., such that the third openings 2201 are aligned with each other), in the embodiment illustrated in FIGS. 31A-31B the second pad 2503 is mis-aligned from the underlying first pad 107, such that the third openings 2201 are not aligned with each other. Any suitable alignment or mis-alignment are fully intended to be included within the scope of the embodiments.

FIGS. 32A and 32B illustrate top down views of the first pad 107 and the second pad 2503 through lines A-A′ and B-B′, respectively, in FIG. 29 in embodiments in which both the first pad 107 and the second pad 2503 are similarly shaped, but with different sizes. In the top down figure illustrates in FIG. 32A, the first pad 107 is a continuous pad (e.g., without the third openings 2201 separating different segments of the first pad 107), and the first pad 107 and the first bond pad via 1605 are concentric with each other. However, any of the shapes (e.g., continuous, discontinuous/segmented, polygonal, etc.) and combinations (concentric, non-concentric, etc.) that have been discussed herein may be utilized to shape the first pad 107.

FIG. 32B illustrates that the second pad 2503 overlying the first pad 107 may be a similar shape as the first pad 107 in a top down view. For example, the second pad 2503 may be continuous without the third openings 2201. However, any of the shapes (continuous, discontinuous/segmented, polygonal, etc.) and combinations (concentric, non-concentric, etc.) that have been discussed herein may be utilized to shape the first pad 107.

Further, while the shape of the second pad 2503 may be the same as the underlying first pad 107, in the embodiment illustrated in FIGS. 32A-32B the second pad 2503 is larger (e.g., has a larger outer diameter or a larger inner diameter) from the underlying first pad 107, such that outer perimeter of the second pad 2503 does not directly overlie the outer perimeter of the first pad 107.

Of course, while a number of combinations of shapes, alignments, and sizes have been described above, these specific combinations are only intended to be illustrative and are not intended to be limiting to the embodiments. Rather, any suitable combination of the shapes, sizes, and alignments presented herein may be combined together as desired. All such combinations are fully intended to be included within the scope of the embodiments.

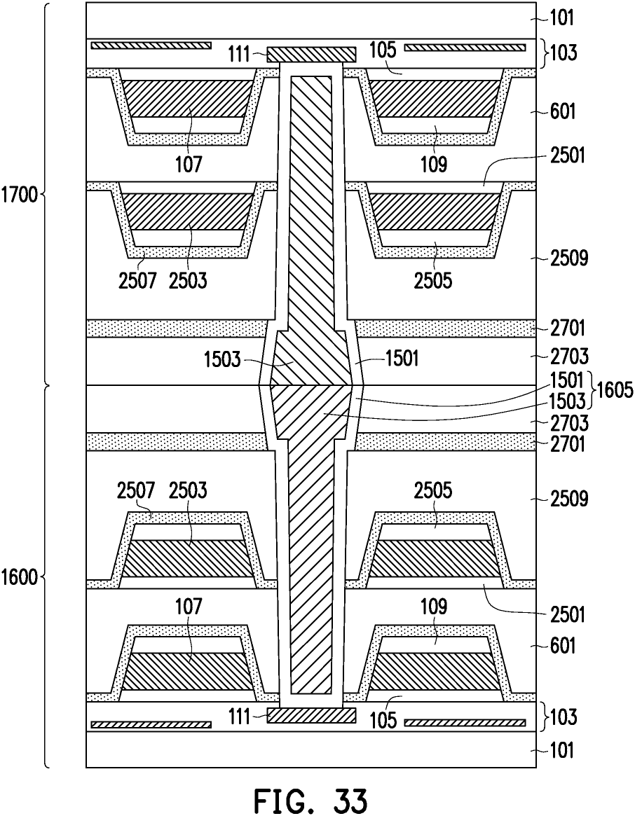

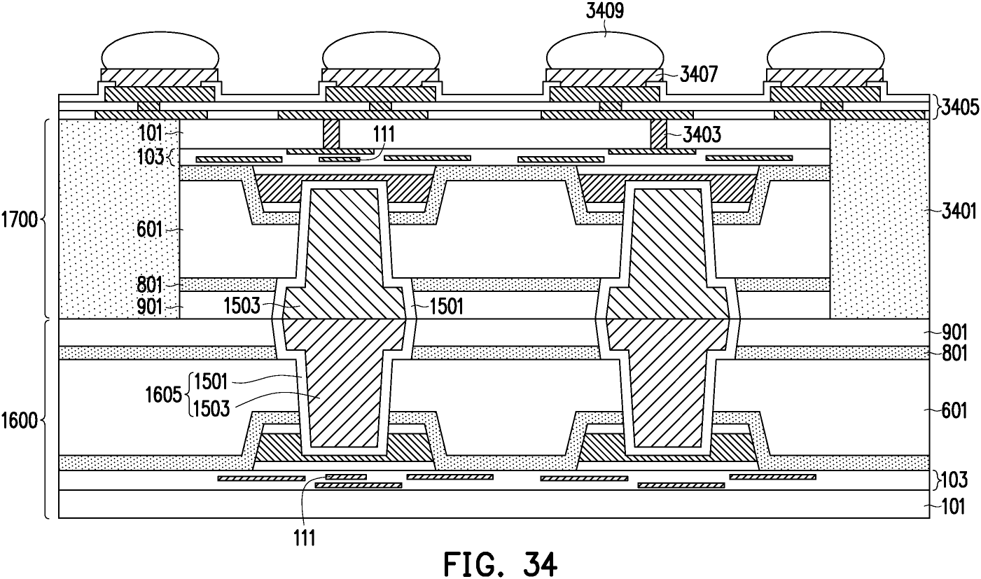

FIG. 33 illustrates a bonding of the first semiconductor device 1600 to the second semiconductor device 1700 in embodiments in which the first bond pad via 1605 extends through the first pad 107 and the second pad 2503 without physically contacting the first pad 107 and the second pad 2503 (as described above with respect to FIGS. 24-32B). In an embodiment the first semiconductor device 1600 may be bonded to the second semiconductor device 1700 as described above with respect to FIG. 17, such as by using a hybrid bonding process. However, any suitable bonding process may be utilized.

FIG. 34 illustrates another embodiment which utilizes the first via bond pads 1605 in a package. In this embodiment the second semiconductor device 1700 is bonded to the first semiconductor device 1600, but the first semiconductor device 1600 has a larger width than the second semiconductor device 1700. In such an embodiment the second semiconductor device 1700 may be encapsulated with an encapsulant 3401 either before or after bonding to the first semiconductor device 1600. In an embodiment the encapsulant 3401 may be a molding compound resin such as polyimide, PPS, PEEK, PES, a heat resistant crystal resin, combinations of these, or the like. If the second semiconductor device 1700 is encapsulated prior to bonding, the encapsulant 3401 may be planarized using, e.g., a chemical mechanical polishing process in order to re-expose the first bond pad vias 1605.

Additionally in this embodiment, the second semiconductor device 1700 may be formed with through substrate vias 3403 in order to provide electrical connections to a backside of the semiconductor substrate 101 of the second semiconductor device 1700. In an embodiment the through substrate vias 3403 may be initially formed in the semiconductor substrate 101 of the second semiconductor device 1700 by forming an opening into the semiconductor substrate 101, lining the opening with a liner, filling a remainder of the opening with a conductive material such as copper, and removing excess material outside of the opening with a planarization process such as a chemical mechanical polishing process. Once done, a backside of the semiconductor substrate 101 may be thinned to expose the conductive material using, e.g., a chemical mechanical planarization process.

Once the TSVs 3403 have been formed, a back-side redistribution structure 3405 may be formed. In the embodiment shown, the back-side redistribution structure 3405 includes a dielectric layer and a metallization pattern (sometimes referred to as redistribution layers or redistribution lines). In some embodiments, the dielectric layer is formed of a polymer, such as polybenzoxazole (PBO), polyimide, benzocyclobutene (BCB), or the like. In other embodiments, the dielectric layer is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer may be formed by any acceptable deposition process, such as spin coating, CVD, laminating, the like, or a combination thereof and then patterned, if desired, to expose underlying conductive elements.

The metallization pattern may be formed on and/or through the dielectric layer. As an example to form the metallization pattern, a seed layer is formed over the dielectric layer. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the metallization pattern. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern.

Another dielectric layer may be formed on the metallization pattern and the dielectric layer. In some embodiments, the another dielectric layer is formed of a polymer, which may be a photo-sensitive material such as PBO, polyimide, BCB, or the like, that may be patterned using a lithography mask. In other embodiments, the dielectric layer is formed of a nitride such as silicon nitride; an oxide such as silicon oxide, PSG, BSG, BPSG; or the like. The dielectric layer may be formed by spin coating, lamination, CVD, the like, or a combination thereof. The dielectric layer is then patterned to form openings exposing portions of the metallization pattern. The patterning may be formed by an acceptable process, such as by exposing the dielectric layer to light when the dielectric layer is a photo-sensitive material or by etching using, for example, an anisotropic etch. If the dielectric layer is a photo-sensitive material, the dielectric layer can be developed after the exposure.

In some embodiments, the back-side redistribution structure 3405 may include any number of dielectric layers and metallization patterns. If more dielectric layers and metallization patterns are to be formed, steps and processes discussed above may be repeated. The metallization patterns may include one or more conductive elements. The conductive elements may be formed during the formation of the metallization pattern by forming the seed layer and conductive material of the metallization pattern over a surface of the underlying dielectric layer and in the opening of the underlying dielectric layer, thereby interconnecting and electrically coupling various conductive lines.

Once the back-side redistribution structure 3405 has been formed, under bump metallizations (UBMs) 3407 are formed for external connections. In an embodiment the UBMs 3407 may comprise three layers of conductive materials, such as a layer of titanium, a layer of copper, and a layer of nickel. However, one of ordinary skill in the art will recognize that there are many suitable arrangements of materials and layers, such as an arrangement of chrome/chrome-copper alloy/copper/gold, an arrangement of titanium/titanium tungsten/copper, or an arrangement of copper/nickel/gold, that are suitable for the formation of the UBMs 3407. Any suitable materials or layers of material that may be used for the UBMs 3407 are fully intended to be included within the scope of the embodiments.

In an embodiment the UBMs 3407 are created by forming each layer over the underlying layers. The forming of each layer may be performed using a plating process, such as electrochemical plating, although other processes of formation, such as sputtering, evaporation, or PECVD process, may also be used depending upon the desired materials. The UBMs 3407 may be formed to have a thickness of between about 0.7 µm and about 10 µm, such as about 5 µm.

FIG. 34 additionally illustrates the formation of first external contacts 3409 on the UBMs 3407. In an embodiment the first external contacts 3409 may be, for example, contact bumps as part of a ball grid array (BGA), although any suitable connection may be utilized. In an embodiment in which the first external contacts 3409 are contact bumps, the first external contacts 3409 may comprise a material such as tin, or other suitable materials, such as silver, lead-free tin, or copper. In an embodiment in which the first external contacts 3409 are tin solder bumps, the first external contacts 3409 may be formed by initially forming a layer of tin through such methods such as evaporation, electroplating, printing, solder transfer, ball placement, etc., to a thickness of, e.g., about 250 µm. Once a layer of tin has been formed on the structure, a reflow may be performed in order to shape the material into the desired bump shape.

By forming the first bond pad vias 1605 as described above, mismatches in the coefficients of thermal expansion between the material of the first bond pad vias 1605 (e.g., copper) and the first pads 701 (e.g., aluminum-copper) can be used as a means to modulate protrusions of the material of the first bond pad vias 1605. This is especially true during annealing processes (e.g., elevated temperatures above 280° C. As such, with a lower thermal expansion, a higher bonding yield can be achieved, especially in embodiments which form 5 nm process node system on integrated circuits.

In accordance with an embodiment, a method of manufacturing a semiconductor device includes: forming metallization layers over a semiconductor substrate; forming a first pad over the metallization layers; depositing one or more passivation layers over the first pad; and forming a first bond pad via through the one or more passivation layers and at least partially through the first pad. In an embodiment, the first pad comprises aluminum and copper. In an embodiment, the method further includes forming a first barrier layer over the metallization layers prior to the forming the first pad. In an embodiment the method further includes bonding the first bond pad via to a second bond pad via. In an embodiment the method further includes depositing a first etch stop layer over the first pad prior to the depositing the one or more passivation layers. In an embodiment, the forming the first bond pad via forms the first bond pad via fully through the first pad and without touching the first pad. In an embodiment, the forming the first bond pad via forms the first bond pad via partially through and in physical contact with the first pad.

In accordance with another embodiment, a method of manufacturing a semiconductor device includes: forming a first pad over a metallization layer, the first pad having a rounded outer perimeter and an inner perimeter; depositing a plurality of passivation layers over the first pad; etching through the plurality of passivation layers to form an opening that extends through the first pad without exposing the first pad; and forming a first bond pad via in the opening. In an embodiment, the first bond pad via has a first portion extending through the first pad and a second portion extending through the first pad, the first portion being separated from the second portion by at least a portion of the plurality of passivation layers. In an embodiment, the first bond pad via is in physical connection with a portion of the metallization layer. In an embodiment, the portion of the metallization layer comprises aluminum. In an embodiment, the etching through the plurality of passivation layers forms the opening to extend through a second pad without exposing the second pad. In an embodiment, the second pad is mis-aligned with respect to the first pad. In an embodiment, the first pad has a first shape, the second pad has the first shape, and the second pad is larger than the first pad.

In accordance with yet another embodiment, a semiconductor device includes: metallization layers over a semiconductor substrate; a first pad over the metallization layers; a plurality of passivation layers over the first pad; and a first bond pad via extending through the plurality of passivation layers and at least partially through the first pad, wherein the first bond pad via shares a planar surface with at least one of the plurality of passivation layers. In an embodiment, the first bond pad via extends partially through the first pad and is in physical contact with the first pad. In an embodiment, the first bond pad via extends fully through the first pad and is not in physical contact with the first pad. In an embodiment, the first pad comprises a plurality of polygons. In an embodiment, the first pad is discontinuous. In an embodiment the semiconductor device further includes a second pad overlying the first pad, the first bond pad via extending fully through the second pad and not in physical contact with the second pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming metallization layers over a semiconductor substrate;
forming a first pad over the metallization layers;
depositing one or more passivation layers over the first pad; and
forming a first bond pad via through the one or more passivation layers and at least partially through the first pad.

2. The method of claim 1, wherein the first pad comprises aluminum and copper.

3. The method of claim 1, wherein the forming the first bond pad via forms the bond pad via with a rounded corner.

4. The method of claim 1, further comprising bonding the first bond pad via to a second bond pad via.

5. The method of claim 1, further comprising depositing a first etch stop layer over the first pad prior to the depositing the one or more passivation layers.

6. The method of claim 1, wherein the forming the first bond pad via forms the first bond pad via fully through the first pad and without touching the first pad.

7. The method of claim 1, wherein the forming the first bond pad via forms the first bond pad via partially through and in physical contact with the first pad.

8. A method of manufacturing a semiconductor device, the method comprising:
forming a first pad over a metallization layer, the first pad having a rounded outer perimeter and an inner perimeter;
depositing a plurality of passivation layers over the first pad;
etching through the plurality of passivation layers to form an opening that extends through the first pad without exposing the first pad; and
forming a first bond pad via in the opening.

9. The method of claim 8, wherein the first bond pad via has a first portion extending through the first pad and a second portion extending through the first pad, the first portion being separated from the second portion by at least a portion of the plurality of passivation layers.

10. The method of claim 8, wherein the first bond pad via is in physical connection with a portion of the metallization layer.

11. The method of claim 10, wherein the portion of the metallization layer comprises aluminum.

12. The method of claim 8, wherein the etching through the plurality of passivation layers forms the opening to extend through a second pad without exposing the second pad.

13. The method of claim 12, wherein the second pad is mis-aligned with respect to the first pad.

14. The method of claim 12, wherein the first pad has a first shape, the second pad has the first shape, and the second pad is larger than the first pad.

15. A semiconductor device comprising:
metallization layers over a semiconductor substrate;
a first pad over the metallization layers;
a plurality of passivation layers over the first pad; and
a first bond pad via extending through the plurality of passivation layers and at least partially through the first pad, wherein the first bond pad via extends away from the semiconductor substrate at least as far as a top one of the plurality of passivation layers.

16. The semiconductor device of claim 15, wherein the first bond pad via extends partially through the first pad and is in physical contact with the first pad.

17. The semiconductor device of claim 15, wherein the first bond pad via extends fully through the first pad and is not in physical contact with the first pad.

18. The semiconductor device of claim 17, wherein the first pad comprises a plurality of polygons.

19. The semiconductor device of claim 17, wherein the first pad is discontinuous.

20. The semiconductor device of claim 15, further comprising a second pad overlying the first pad, the first bond pad via extending fully through the second pad and not in physical contact with the second pad.
